(19) United States
(12) Patent Application Publication
(10) Pub. No.: US 2025/0351703 A1
(43) Pub. Date: Nov. 13, 2025

(54) DISPLAY DEVICE, METHOD OF MANUFACTURING THE SAME, AND ELECTRONIC DEVICE COMPRISING THE SAME

(71) Applicant: Samsung Display Co., LTD., Yongin-si (KR)

(72) Inventor: In Young JUNG, Yongin-si (KR)

(73) Assignee: Samsung Display Co., LTD., Yongin-si (KR)

(21) Appl. No.: 18/970,626

(22) Filed: Dec. 5, 2024

(30) Foreign Application Priority Data
May 7, 2024 (KR) 10-2024-0059875

(51) Int. Cl. H10K 59/80; H10K 59/12; H10K 59/122; H10K 59/131

(52) U.S. Cl. CPC H10K 59/80521; H10K 59/1201; H10K 59/122; H10K 59/131; H10K 59/80516

(57) ABSTRACT

Provided is a display device, a method of manufacturing a display device, and an electronic device comprising a display device. The display device includes: a base layer; an anode electrode disposed on the base layer, the anode electrode including a first portion and a second portion; a light emitting layer disposed on the anode electrode; a cathode bridge layer disposed on the base layer, the cathode bridge layer being disposed in a same layer as the anode electrode and spaced apart from the anode electrode; a residual sacrificial layer disposed on the first portion of the light emitting layer; and a cathode electrode disposed on light emitting layer, the cathode electrode including a portion disposed on the second portion of the light emitting layer, the cathode electrode including another portion disposed on the cathode bridge layer.

### CROSS-REFERENCE TO RELATED APPLICATION

This application claims priority to and benefits of Korean Patent Application No. 10-2024-0059875 under 35 U.S.C. § 119, filed on May 7, 2024 in the Korean Intellectual Property Office, the entire contents of which are incorporated herein by reference.

### BACKGROUND

### 1. Technical Field

The disclosure generally relates to a display device, a method of manufacturing a display device, and an electronic device comprising a display device. More particularly, the disclosure relates to a display device capable of reducing a voltage drop risk of a cathode electrode and a method of manufacturing the display device.

### 2. Description of the Related Art

With the development of information technologies, the importance of a display device which is a connection medium between a user and information increases. The display device may include an organic light emitting diode (OLED), and sub-pixels adjacent to each other may be formed using the OLED.

In the OLED, a light-emitting layer could be positioned between the hole and electron transport units, as well as an electron and hole transport unit inside the OLED. Excitons can be produced in the light-emitting layer through the recombination of electrons from the electron transport unit and holes from the hole transport unit. Light may be produced as the excitons are converted from an excited state to a ground state. For the reliability of an electrical signal supplied to a sub-pixel, it is desirable to reduce a voltage drop risk due to an increase in resistance of a conductive structure to which the electrical signal is supplied.

### SUMMARY

Embodiments provide a display device, a method of manufacturing a display device, and an electronic device comprising a display device, in which a voltage drop risk of a cathode electrode is reduced.

Embodiments also provide a display device having improved display quality and a method of manufacturing a display device having improved display quality.

Embodiments also provide a display device, a method of manufacturing a display device, and an electronic device comprising a display device, in which process steps are simplified, to improve convenience of manufacturing processes and reduce process cost.

In accordance with an aspect of the disclosure, there is provided a display device including: a base layer; an anode electrode disposed on the base layer, the anode electrode including a first portion and a second portion; a light emitting layer disposed on the anode electrode; a cathode bridge layer disposed on the base layer, the cathode bridge layer being disposed in a same layer as the anode electrode and spaced part from the anode electrode; a residual sacrificial layer disposed on the first portion of the light emitting layer; and a cathode electrode disposed on the light emitting layer, the cathode electrode including a portion disposed on the second portion of the light emitting layer, the cathode electrode including another portion disposed on the cathode bridge layer.

The display device may further include a first power line and a second power line, disposed on the base layer, the first power line and the second power line, respectively forming a first voltage potential and a second voltage potential. The first power line and the second power line may be disposed closer to the base layer than the cathode bridge layer in a thickness direction. The anode electrode may include anode electrodes adjacent to each other. The cathode bridge layer may be disposed between the adjacent anode electrodes, and be electrically connected to the second power line.

The anode electrode and the cathode bridge layer may include a structure in which a transparent conductive material, a reflective conductive material, and a transparent conductive material are sequentially disposed.

The anode electrode and the cathode bridge layer may include a structure in which ITO/Ag/ITO are sequentially stacked in a thickness direction. The cathode electrode may include a silver-magnesium (AgMg) alloy. The residual sacrificial layer may include aluminum (Al).

The display device may further include a pixel defining layer exposing the second portion of the anode electrode and the cathode bridge layer. An upper surface and an outer surface of the residual sacrificial layer may be covered by the pixel defining layer. An inner surface of the residual sacrificial layer may be exposed by the pixel defining layer, and be in direct contact with the cathode electrode.

The display device may include a display area including sub-pixel areas including a first sub-pixel area, a second sub-pixel area, and a third sub-pixel area. The anode electrode, the light emitting layer, and the cathode electrode may form a light emitting element defined in the display area. The cathode bridge layer may be disposed in the display area. The light emitting element may include a first light emitting element which is formed in the first sub-pixel area and provides light of a first color, a second light emitting element which is formed in the second sub-pixel area and provides light of a second color, and a third light emitting element which is formed in the third sub-pixel area and provides light of a third color.

In accordance with another aspect of the disclosure, there is provided a display device including: a base layer; a pixel-circuit layer disposed on the base layer, the pixel-circuit layer including a pixel circuit, a protective layer covering the pixel circuit, and a cathode bridge layer adjacent to the protective layer in a plan direction in which the base layer is disposed; a light emitting element disposed on the pixel-circuit layer; and a pixel defining layer disposed on the pixel-circuit layer, wherein the light emitting element includes an anode electrode disposed on the protective layer, a light emitting layer including a portion disposed on the anode electrode, and a cathode electrode including a portion disposed on the light emitting layer, wherein the pixel defining layer covers a portion of the anode electrode, and wherein another portion of the cathode electrode is electrically connected to the cathode bridge layer through a contact portion penetrating the pixel defining layer and the protective layer.

The cathode electrode may cover un upper surface of the light emitting layer and a side surface of the light emitting layer. A portion of the pixel defining layer may be disposed between the light emitting layer and the anode electrode.

The anode electrode may include an uppermost anode electrode portion having a first thickness in a thickness direction. The cathode bridge layer may include an uppermost cathode bridge portion having a second thickness in the thickness direction. The second thickness may be greater than the first thickness.

The uppermost anode electrode portion may include ITO, and the first thickness may be about 50 Å to about 100 Å. The uppermost cathode bridge portion may include Ti, and the second thickness may be about 1000 Å to about 2000 Å.

The pixel circuit may include a transistor including a source electrode and a drain electrode. The cathode bridge layer, the source electrode, and the drain electrode may be formed in a same layer.

In accordance with still another aspect of the disclosure, there is provided a method of manufacturing a display device, the method including: forming a pixel-circuit layer including a pixel circuit disposed on a base layer; patterning an anode electrode and a cathode bridge layer disposed on the pixel-circuit layer; forming a base light emitting layer and a base sacrificial layer, which cover the anode electrode and the cathode bridge layer; patterning, on the base sacrificial layer, a photoresist layer including an opening, a first photoresist layer, and a second photoresist layer, using a mask including a half-tone portion, a full-tone portion in a thickness direction, and a blocking portion, wherein the first photoresist layer corresponds to a position of the full-tone portion and the second photoresist layer corresponds to a position of the half-tone portion in the thickness direction; and etching the base light emitting layer and the base sacrificial layer, based on the photoresist layer, wherein the etching of the base light emitting layer and the base sacrificial layer includes: providing a light emitting layer by removing a portion of the base light emitting layer, and exposing the cathode bridge layer.

In the etching of the base light emitting layer and the base sacrificial layer, the first photoresist layer may overlap a position of the light emitting layer to be manufactured, the second photoresist layer may not overlap the light emitting layer and the cathode bridge layer, and the opening may overlap the cathode bridge layer.

The exposing of the cathode bridge layer and the providing of the light emitting layer may be performed based on the photoresist layer as a same etch mask.

The patterning of the anode electrode and the patterning of the cathode bridge layer may be performed through a same process.

The etching of the base light emitting layer and the base sacrificial layer may include forming a sacrificial layer on the light emitting layer by removing at least a portion of the base sacrificial layer, using a wet etching process. The method may further include: patterning a pixel defining layer exposing at least a portion of the sacrificial layer and at least a portion of the cathode bridge layer; exposing the light emitting layer by removing at least a portion of the sacrificial layer; and forming a cathode electrode electrically connected to the light emitting layer and the cathode bridge layer. The exposing of the light emitting layer may include forming a residual sacrificial layer disposed on a portion of the light emitting layer.

In accordance with still another aspect of the disclosure, there is provided a method of manufacturing a display device, the method including: forming, on a base layer, a pixel-circuit layer including a pixel circuit, a cathode bridge layer, and a protective layer covering the pixel circuit and the cathode bridge layer; patterning, on the pixel-circuit layer, an anode electrode and a pixel defining layer covering the anode electrode; forming a base light emitting layer and a base sacrificial layer, which cover the anode electrode and the pixel defining layer; patterning, on the base sacrificial layer, a photoresist layer including a first photoresist layer and a second photoresist layer, using a mask including a half-tone portion, a full-tone portion, and a blocking portion, wherein the first photoresist layer corresponds to a position of the full-tone portion in a thickness direction and the second photoresist layer corresponds to a position of the half-tone portion in the thickness direction; and etching the base light emitting layer, the base sacrificial layer, the pixel defining layer, and the protective layer, based on the photoresist layer, wherein the etching of the base light emitting layer includes: providing a light emitting layer by removing a portion of the base light emitting layer, and exposing the cathode bridge layer.

The pixel circuit may include a transistor including a source electrode and a drain electrode. The cathode bridge layer may be formed through a same process as the source electrode and the drain electrode.

The etching of the base light emitting layer may include forming a sacrificial layer on the light emitting layer by removing at least a portion of the base sacrificial layer, using a wet etching process. The exposing of the cathode bridge layer may include forming a lower exposure hole penetrating the protective layer and the pixel defining layer.

The method may further include entirely exposing un upper surface of the light emitting layer by removing the sacrificial layer; and forming a cathode electrode. A portion of the cathode electrode may be electrically connected to the light emitting layer, and another portion of the cathode electrode may be electrically connected to the cathode bridge layer through the lower exposure hole.

In accordance with an aspect of the disclosure, there is provided an electronic device, including: a processor that provides input image data; a display device that displays an image based on the input image data, the display device including sub-pixel areas; and a power supply that supplies power to the display device. The display device may include: a base layer; an anode electrode disposed on the base layer, the anode electrode including a first portion and a second portion; a light emitting layer disposed on the anode electrode; a cathode bridge layer disposed on the base layer, the cathode bridge layer being disposed in a same layer as the anode electrode and spaced apart from the anode electrode; a residual sacrificial layer disposed on the first portion of the light emitting layer; and a cathode electrode disposed on the light emitting layer, the cathode electrode including a portion disposed on the second portion of the light emitting layer, the cathode electrode including another portion disposed on the cathode bridge layer.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be. Like reference numerals refer to like elements throughout.

FIG. 1 is a schematic plan view illustrating a display device in accordance with an embodiment of the disclosure.

FIG. 2 is a schematic block diagram illustrating an electrical connection structure of a light emitting element included in a pixel in accordance with an embodiment of the disclosure.

FIG. 3 is a schematic sectional view illustrating a light emitting element in accordance with an embodiment of the disclosure.

FIG. 4 is a schematic block diagram illustrating an electrical path through which a cathode signal is supplied in accordance with an embodiment of the disclosure.

FIG. 5 is a schematic sectional view illustrating a display device in accordance with a first embodiment of the disclosure.

FIG. 6 is a schematic sectional view illustrating a display device in accordance with a second embodiment of the disclosure.

FIG. 7 is a schematic sectional view illustrating an anode electrode and a cathode bridge layer in accordance with an embodiment of the disclosure.

FIGS. 8 to 25 are schematic sectional views illustrating process steps of a method of manufacturing the display device in accordance with the first embodiment of the disclosure.

FIGS. 26 to 36 are schematic sectional views illustrating process steps of a method of manufacturing the display device in accordance with the second embodiment of the disclosure.

FIG. 37 is a schematic block diagram illustrating an electronic device including a display device in accordance with an embodiment.

FIG. 38 is a schematic diagram illustrating an example where the electronic device of FIG. 37 is implemented as a smartphone.

FIG. 39 is a schematic diagram illustrating an example where the electronic device of FIG. 37 is implemented as a tablet computer.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which are formed using g semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts. The disclosure generally relates to a display device, a method of manufacturing a display device, and an electronic device comprising a display device. Hereinafter, a display device, a method of manufacturing a display device, and an electronic device comprising a display device in accordance with an embodiment of the disclosure will be described with reference to the accompanying drawings.

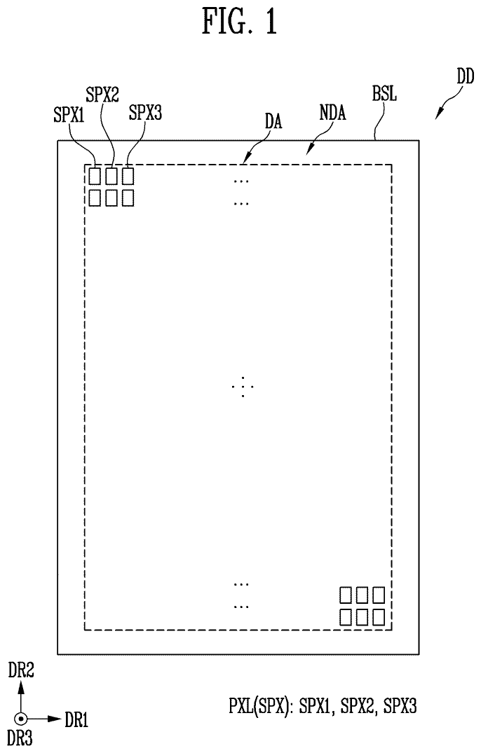

FIG. 1 is a schematic plan view illustrating a display device in accordance with an embodiment of the disclosure.

Referring to FIG. 1, the display device DD may include a base layer BSL and pixels PXL disposed on the base layer BSL. The display device DD may further include a driving circuit (e.g., a scan driver and a data driver) for driving the pixels PXL, lines, pads, and the like.

The display device DD (or the base layer BSL) may include a display area DA and a non-display area NDA. The non-display area NDA may mean an area except the display area DA. The non-display area NDA may surround at least a portion of the display area DA.

The base layer BSL may form a base surface of the display device DD. In some embodiments, the base layer BSL may be a lower substrate for disposing layers forming the display device DD. The base layer BSL may be a rigid or flexible substrate or film. For example, the base layer BSL may include a glass material. In another example, the base layer BSL may include a silicon material. In another example, the base layer BSL may include polyimide. However, the disclosure is not limited thereto.

The display area DA may include the pixels PXL. However, the non-display area NDA may not include the pixels PXL. For example, the driving circuit, the lines, and the pads, which are connected to the pixels PXL of the display area DA, may be disposed in the non-display area NDA.

In accordance with an embodiment, the pixels PXL (or sub-pixels SPX) may be arranged according to a stripe arrangement structure, a PenTile® arrangement structure, or the like. However, the disclosure is not limited thereto, and various embodiments may be applied in the disclosure.

In accordance with an embodiment, a pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form one pixel unit capable of emitting lights of various colors.

Each of the first sub-pixel SPX1, the second sub-pixel SPX2, and the third sub-pixel SPX3 may emit light of a color.

For example, the first sub-pixel SPX1 may emit light of red (e.g., the first color), the second sub-pixel SPX2 may emit light of green (e.g., the second color), and the third sub-pixel SPX3 may emit light of blue (e.g., the third color). The red pixel may provide light in a wavelength band of about 600 nm to about 750 nm. The green pixel may provide light in a wavelength band of about 480 nm to about 560 nm. The blue pixel may provide light in a wavelength band of about 370 nm to about 460 nm.

In accordance with an embodiment, a number of the second sub-pixels SPX2 may be greater than a number of the first sub-pixels SPX1, and may also be greater than a number of the third sub-pixels SPX3. However, the color, kind, and/or number of first, second, and third sub-pixels SPX1, SPX2, and SPX3 constituting each pixel unit are not limited to a specific example.

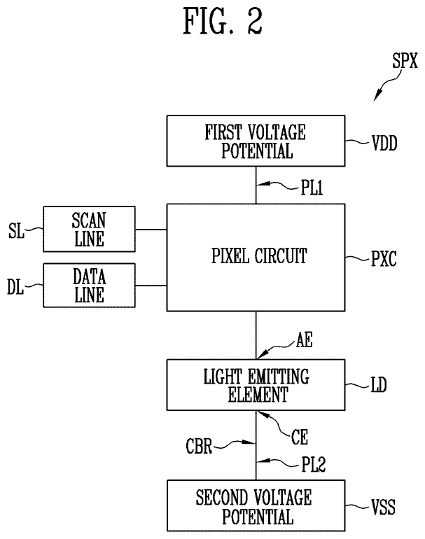

FIG. 2 is a schematic block diagram illustrating an electrical connection structure of a light emitting element included in a pixel in accordance with an embodiment of the disclosure. For example, FIG. 2 may illustrate an electrical connection structure including a pixel circuit PXC corresponding to each sub-pixel SPX.

Referring to FIG. 2, the sub-pixel SPX may include a light emitting element LD and a pixel circuit PXC configured to drive the light emitting element LD. The display device DD may include a scan line SL, a data line DL, a first power line PL1, a second power line PL2, and a cathode bridge layer CBR.

The pixel circuit PXC may include at least one circuit element. For example, the pixel circuit PXC may include transistors and at least one storage capacitor. For example, the pixel circuit PXC may include a driving transistor, a switching transistor, and a storage capacitor. However, the disclosure is not limited thereto, and the pixel circuit PXC may further include an additional circuit element. For example, the pixel circuit PXC may include more or less than two transistors and more than one storage capacitor.

The pixel circuit PXC may be electrically connected to the scan line SL and the data line DL. For example, the scan line SL and the data line may be disposed parallel to each other. In another example, the scan line SL and the data line may be disposed perpendicular to each other. The scan line SL may supply a scan signal to the pixel circuit PXC. In some embodiments, the scan line SL may be electrically connected to a gate electrode of the switching transistor of the pixel circuit PXC. The light emitting element LD may be configured to emit light corresponding to a data signal provided from the data line DL.

The pixel circuit PXC may be electrically connected to the first power line PL1 and the second power line PL2. For example, an anode electrode AE of the light emitting element LD may be electrically connected to the pixel circuit PXC and the first power line PL1, and a cathode electrode CE of the light emitting element LD may be electrically connected to the second power line PL2. The first power line PL1 and the second power line PL2 may be disposed on the base layer BSL.

A power source of the first power line PL1 and a power source of the second power line PL2 may have different potentials. For example, the power source of the first power line PL1 may be a high-potential pixel power source supplied with a power source from a first voltage potential VDD, and the power source of the second power line PL2 may be a low-potential pixel power source supplied with a power source from a second voltage potential VSS. A potential difference between the power source of the first power line PL1 and the power source of the second power line PL2 may be set equal to or higher than a threshold voltage of light emitting elements LD.

The first power line PL1 may be electrically connected to the pixel circuit PXC (e.g., the driving transistor). In some embodiments, the second power line PL2 may be electrically connected to the cathode electrode CE of the light emitting element LD through the cathode bridge layer CBR. The first and second power lines PL1 and PL2 may be more adjacent to the base layer BSL than the cathode bridge layer CBR.

Light emitting elements LD may be electrically connected in a forward direction between the first power line PL1 and the second power line PL2, to respectively form effective light sources. These effective light sources gather to constitute the light emitting elements LD of the sub-pixel SPX.

The light emitting elements LD may emit light with a luminance corresponding to a driving current supplied through the pixel circuit PXC. The pixel circuit PXC may supply a driving current corresponding to the data signal to the light emitting element LD during each frame period. The light emitting element LD may emit light with a luminance corresponding to a current flowing therethrough.

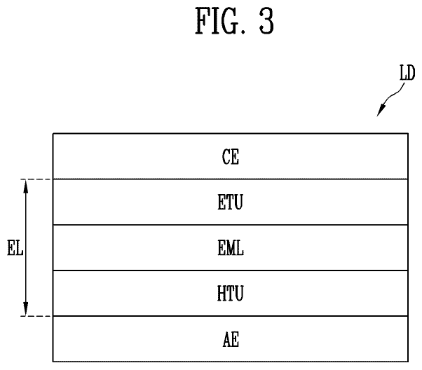

FIG. 3 is a schematic sectional view illustrating a light emitting element in accordance with an embodiment of the disclosure.

Referring to FIG. 3, the light emitting element LD may include an anode electrode AE, a light emitting layer EL, and a cathode electrode CE.

The anode electrode AE may supply an anode signal to the light emitting layer EL. The light emitting layer EL may be disposed on the anode electrode AE.

The light emitting layer EL may include layers. For example, the light emitting layer EL may include a hole transport unit HTU disposed on the anode electrode AE, a light emitting unit EML (or light generation layer) disposed on the hole transport unit HTU, and an electron transport unit ETU disposed on the light emitting unit EML. Each of the layers forming the light emitting layer EL may include an organic material. In some embodiments, each of the layers forming the light emitting layer EL may further include a metal-containing compound, an inorganic material such as a quantum dot, or the like.

The hole transport unit HTU may include multiple layers having different materials. In an example, the hole transport unit HTU may include a hole injection layer and a hole transport layer. In some embodiments, the hole transport unit HTU may further include a light emitting auxiliary layer, an electron blocking layer, and the like.

The light emitting unit EML may include a material capable of emitting light of a color. The light emitting unit EML may include a host and a dopant. The host of the light emitting unit EML may be a light emitting material capable of capturing carriers (electrons and holes) for generating light, and may induce excitons to be efficiently generated. The dopant of the light emitting layer EML may include a phosphorescent dopant and a fluorescent dopant. In some embodiments, examples of the dopant are not particularly limited. In some embodiments, the dopant may include an organic material. The dopant may also include a metal complex and the like.

The electron transport unit ETU may include a multi-layer structure having layers including different materials. The electron transport unit ETU may include an electron injection layer and an electron transport layer. In some embodiments, the electron transport unit ETU may further include an electron buffer layer, a hole blocking layer, and the like.

The cathode electrode CE may supply a cathode signal to the light emitting layer EL. The cathode electrode CE may be disposed on the top (or upper surface) of the light emitting layer EL. For example, the cathode electrode CE may be disposed on the electron transport unit ETU.

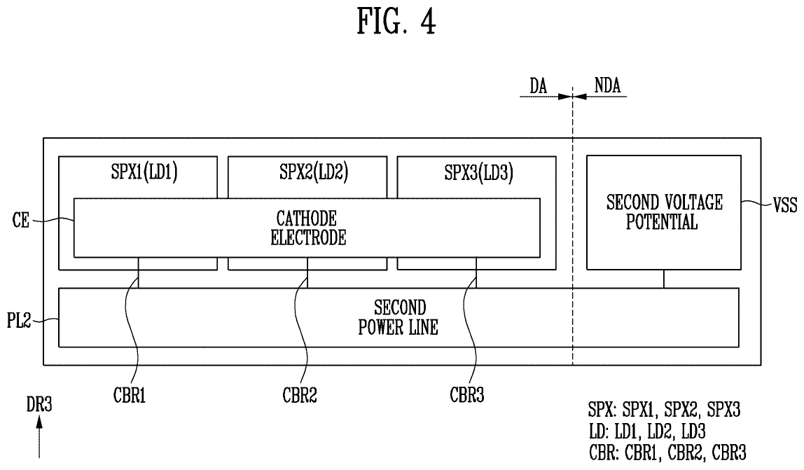

The light emitting element LD may emit light of a color. For example, the light emitting element LD may include a first light emitting element LD1 (see FIG. 4) emitting light of a first color, a second light emitting element LD2 (see FIG. 4) emitting light of a second color, and a third light emitting element LD3 (see FIG. 4) emitting light of a third color.

FIG. 4 is a schematic block diagram illustrating an electrical path through which a cathode signal is supplied in accordance with an embodiment of the disclosure. For example, FIG. 4 may schematically illustrate positions of components and an electrical connection relationship between the components, based on the display area DA and the non-display area NDA.

Referring to FIG. 4, an electrical path through which a cathode voltage is supplied in accordance with an embodiment of the disclosure may be defined such that a voltage drop risk can be reduced.

In some embodiments, the cathode voltage may be supplied through the second power line PL2, and the second power line PL2 may be electrically connected to the cathode electrode CE as a target to which the cathode voltage is supplied through the cathode bridge layer CBR. In some embodiments, a thickness of the second power line PL2 in a third direction DR3 may be thicker than a thickness of the cathode electrode CE in the third direction DR3.

The light emitting element LD may include a first light emitting element LD1 included in a first sub-pixel SPX1, a second light emitting element LD2 included in a second sub-pixel SPX2, and a third light emitting element LD3 included in a third sub-pixel SPX3. The cathode electrode CE may be disposed throughout the first to third sub-pixels SPX1 to SPX3.

The second power line PL2 may be electrically connected to the second voltage potential VSS in the non-display area NDA. The second power line PL2 may be electrically connected to the cathode bridge layer CBR and the cathode electrode CE in the display area DA.

The cathode bridge layer CBR may be disposed in the display area DA. The cathode bridge layer CBR may overlap the second power line PL2 in a plan view.

A plan defined in this specification is a plan extending in a first direction DR1 and a second direction DR2, and may be defined with respect to a plan on which the base layer BSL is disposed. In some embodiments, a third direction DR3 may be a thickness direction of the base layer BSL. The third direction DR3 may be a light output direction of the display device DD.

The cathode bridge layer CBR may include a first cathode bridge layer CBR1 included in the first sub-pixel SPX1, a second cathode bridge layer CBR2 included in the second sub-pixel SPX2, and a third cathode bridge layer CBR3 included in the third sub-pixel SPX3. The first cathode bridge layer CBR1 may be electrically connected to a first portion of the cathode electrode CE, which forms the first light emitting element LD1. The second cathode bridge layer CBR2 may be electrically connected to a second portion of the cathode electrode CE, which forms the second light emitting element LD2. The third cathode bridge layer CBR3 may be electrically connected to a third portion of the cathode electrode CE, which forms the third light emitting element LD3.

As described above, the path through which the cathode voltage is applied may be defined in the second power line PL2 having a relatively small resistance. The path through which the cathode voltage is applied may be defined as a small portion in the cathode electrode CE having a relatively large resistance. As a result, a voltage drop risk of the cathode voltage can be substantially reduced. Accordingly, the operation reliability of the light emitting element LD can be improved, and the display device DD having improved display quality can be provided.

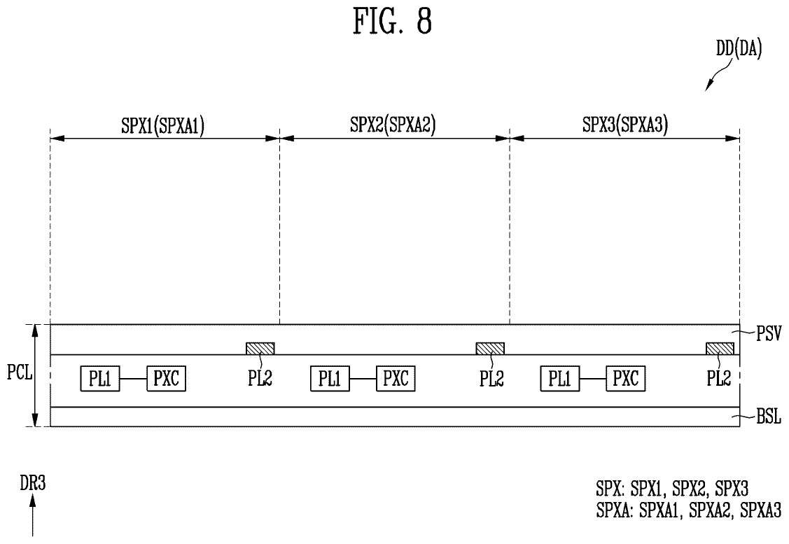

Moreover, the cathode bridge layer CBR forming the path through which the cathode voltage is supplied may be formed. The cathode bridge layer CBR may be patterned in an etching process for manufacturing the light emitting layer EL. Accordingly, the path through which the cathode voltage is supplied can be properly formed without the use of additional masks. This will be described in detail later in conjunction with a method of manufacturing the display device DD, which is described with reference to the drawings from FIG. 8.

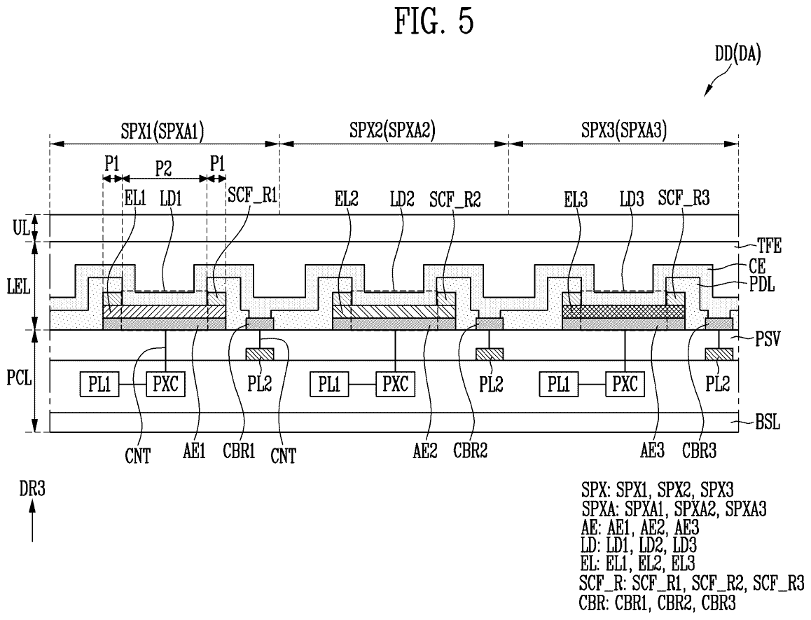

A display device DD in accordance with a first electrode of the disclosure will be described with reference to FIG. 5. In FIG. 5, descriptions of portions overlapping the portions described above will be simplified or will not be repeated.

FIG. 5 is a schematic sectional view illustrating a display device in accordance with a first embodiment of the disclosure. FIG. 5 illustrates a sectional structure of the display device DD in the display area DA.

In accordance with the first embodiment of the disclosure, a cathode bridge layer CBR may be patterned through a same process as an anode electrode AE.

Referring to FIG. 5, the display device DD in accordance with the embodiment of the disclosure may include a pixel-circuit layer PCL, a light-emitting-element layer LEL disposed on the pixel defining layer PCL, and an upper layer UL disposed on the light-emitting-element layer LEL, and may include a sub-pixel SPX corresponding to a sub-pixel area SPXA.

In some embodiments, the sub-pixel SPX may form the sub-pixel area SPXA. The sub-pixel area SPXA may be an area in which light of a color is viewed. For example, the sub-pixel area SPXA may include a first sub-pixel area SPXA1 which a first sub-pixel SPX1 forms and in which light of a first color is provided, a second sub-pixel area SPXA2 which a second sub-pixel SPX2 forms and in which light of a second color is provided, and a third sub-pixel area SPXA3 which a third sub-pixel SPX3 forms and in which light of a third color is provided.

The pixel-circuit layer PCL may include a base layer BSL, a pixel circuit PXC, a first power line PL1, a second power line PL2, and a protective layer PSV.

In some embodiments, the pixel-circuit layer PCL may be designated as a backplane layer.

The pixel circuit PXC may be disposed on the base layer BSL to drive the light emitting element LD. The first power line PL1 may be disposed on the base layer BSL, and the second power line PL2 may be disposed on the first power line PL1 and pixel circuit PXC. The pixel-circuit layer PCL may include conductive layers and insulating layers, and the conductive layers may form the pixel circuit PXC, the first power line PL1, and the second power line PL2. The pixel circuit PXC may be included in a corresponding sub-pixel SPX. For example, the first power line PL1 and the pixel circuit PXC may be electrically connected to each other.

In some embodiments, a source electrode and/or a drain electrode of a transistor included in the pixel circuit PXC may be disposed in a same layer as the second power line PL2, and include a same material as the second power line PL2.

The protective layer PSV may be formed at an upper portion of the pixel-circuit layer PCL. The protective layer PSV may be disposed over the first power line PL1, the second power line PL2, and the pixel circuit PXC. The protective layer PSV may cover the first power line PL1, the second power line PL2, and the pixel circuit PXC.

The protective layer PSV may be a via layer. For example, a contact portion CNT may be formed in the protective layer PSV. The contact portion CNT may penetrate through the protective layer PSV. A portion of the contact portion CNT may electrically connect the pixel circuit PXC and the anode electrode AE to each other. Another contact portion CNT may electrically connect the cathode bridge layer CBR to the second power line PL2.

The protective layer PSV may be a planarization layer. In some embodiments, the protective layer PSV may include an organic material. For example, the organic material may include at least one of acrylic resin, epoxy resin, phenolic resin, polyamide resin, and polyimide resin. However, the disclosure is not limited thereto. For example, the protective layer PSV may include an inorganic material.

The light-emitting-element layer LEL may include the light emitting element LD, and be disposed on the pixel-circuit layer PCL. The light-emitting-element layer LEL may include the anode electrode AE, the cathode bridge layer CBR, a light emitting layer EL, a residual sacrificial layer SCF_R, a pixel defining layer PDL, a cathode electrode CE, and an encapsulation layer TFE.

The anode electrode AE may be disposed on the pixel-circuit layer PCL. For example, the anode electrode AE may be disposed on the protective layer PSV. The anode electrode AE may be electrically connected to the pixel circuit PXC through the contact portion CNT. The anode electrode AE may include a first anode electrode AE1 disposed in the first sub-pixel area SPXA1, a second anode electrode AE2 disposed in the second sub-pixel area SPXA2, and a third anode electrode AE3 disposed in the third sub-pixel area SPXA3.

The anode electrode AE may include various conductive materials. For example, the anode electrode AE may include a transparent conductive material. For example, the anode electrode AE may include at least one of transparent conductive materials such as indium tin oxide (ITO), indium zinc oxide (IZO), zinc oxide (ZnOₓ), indium gallium zinc oxide (IGZO), and indium tin zinc oxide (ITZO). The anode electrode AE may include an opaque conductive material capable of reflecting light. For example, the anode electrode AE may include at least one selected from the group consisting of titanium nitride (TiN), silver (Ag), and aluminum (Al).

In some embodiments, the anode electrode AE may include multiple layers. For example, the anode electrode AE may have a structure in which a transparent conductive material/a reflective conductive material/a transparent conductive material are sequentially disposed. For example, the anode electrode AE may include a structure in which ITO/Ag/ITO are sequentially stacked.

The cathode bridge layer CBR may be disposed on the pixel-circuit layer PCL. For example, the anode electrode AE may be disposed on the protective layer PSV. The cathode bridge layer CBR may be electrically connected to the second power line PL2 through the contact portion CNT. The cathode bridge layer CBR may include a first cathode bridge layer CBR1 which is disposed in the first sub-pixel area SPXA1 and is adjacent to the first anode electrode AE1, a second cathode bridge layer CBR2 which is disposed in the second sub-pixel area SPXA2 and is adjacent to the second anode electrode AE2, and a third cathode bridge layer CBR3 which is disposed in the third sub-pixel area SPXA3 and is adjacent to the third anode electrode AE3.

The cathode bridge layer CBR may be covered by the pixel defining layer PDL, and at least a portion of a top surface (or upper surface) of the cathode bridge layer CBR may be exposed by the pixel defining layer PDL.

The cathode bridge layer CBR may be patterned through a same process as the anode electrode AE, and include a same material as the anode electrode AE. For example, the cathode bridge layer CBR may include the transparent conductive material described above with reference to the anode electrode AE. In some embodiments, the cathode bridge layer CBR may also include a multi-layer structure. The cathode bridge layer CBR may have a structure in which a transparent conductive material/a reflective conductive material/a transparent conductive material are sequentially disposed. For example, the cathode bridge layer CBR may include a structure in which ITO/Ag/ITO are sequentially stacked.

The cathode bridge layer CBR may be a bridge structure for forming a cathode electrical path. For example, the cathode bridge layer CBR may be disposed in an area adjacent to the light emitting layer EL in the display area DA, and accordingly, a risk such as a voltage drop in the display device DD can be reduced.

The light emitting layer EL may be disposed on the anode electrode AE. The light emitting layer EL may include a first light emitting layer EL1 which is disposed on the first anode electrode AE1 and forms the first sub-pixel SPX1, a second light emitting layer EL2 which is disposed on the second anode electrode AE2 and forms the second sub-pixel SPX2, and a third light emitting layer EL3 which is disposed on the third anode electrode AE3 and forms the third sub-pixel SPX3.

The residual sacrificial layer SCF_R may be disposed on the light emitting layer EL. The residual sacrificial layer SCF_R may be disposed on a first portion P1 of the light emitting layer EL, and expose a second portion P2 of the light emitting layer EL. A top surface (or upper surface) and an outer surface of the residual sacrificial layer SCF_R may be covered by the pixel defining layer PDL. An inner surface of the residual sacrificial layer SCF_R may be exposed by the pixel defining layer PDL, and be directly adjacent to the cathode electrode CE.

The residual sacrificial layer SCF_R may be a residue of a sacrificial layer formed to protect the light emitting layer EL when the light emitting layer EL is manufactured. Accordingly, as the residual sacrificial layer SCF_R is formed, damage of the light emitting layer EL during a process of manufacturing the display device DD is prevented so that the light emitting element LD having improved reliability can be manufactured.

In some embodiments, the residual sacrificial layer SCF_R may include various materials. For example, the residual sacrificial layer SCF_R may include aluminum. However, the disclosure is not limited thereto.

The residual sacrificial layer SCF_R may include a first residual sacrificial layer SCF_R1 disposed on the first light emitting layer EL1 in the first sub-pixel area SPXA1, a second residual sacrificial layer SCF_R2 disposed on the second light emitting layer EL2 in the second sub-pixel area SPXA2, and a third residual sacrificial layer SCF_R3 disposed on the third light emitting layer EL3 in the third sub-pixel area SPXA3.

The pixel defining layer PDL may be disposed on the protective layer PSV, and be disposed on the residual sacrificial layer SCF_R. The pixel defining layer PDL may expose the second portion P2 of the light emitting layer EL. The pixel defining layer PDL may define an area in which the light emitting layer EL and the cathode electrode CE are electrically connected to each other.

The pixel defining layer PDL may include an inorganic material. For example, the pixel defining layer PDL may include silicon oxide (SiOₓ) and silicon nitride (SiNₓ). However, the disclosure is not limited thereto. The pixel defining layer PDL may include a multi-layer structure. For example, the pixel defining layer PDL may include a multi-layer structure in which silicon oxide (SiOₓ) and silicon nitride (SiNₓ) are alternately disposed.

The cathode electrode CE may be disposed on the pixel defining layer PDL and the light emitting layer EL. The cathode electrode CE may be disposed throughout the first to third sub-pixel areas SPXA1 to SPXA3. The cathode electrode CE may be a common electrode of first to third light emitting elements LD1 to LD3.

The cathode electrode CE may include various conductive materials. For example, the cathode electrode CE may include silver (Ag), and further include an additional metal. The additional metal may include at least one of magnesium (Mg), aluminum (Al), copper (Cu), calcium (Ca), and barium (Ba). For example, the cathode electrode CE may include a silver-magnesium (AgMg) alloy. The additional metal may reduce or prevent an aggregation phenomenon of silver (Ag) serving as a host metal, and improve the stability of a thin film formed by the cathode electrode CE. However, the disclosure is not limited thereto.

A portion of the cathode electrode CE may be electrically connected to the second portion of the light emitting layer EL. Another portion of the cathode electrode CE may be electrically connected to a portion of the cathode bridge layer CBR, which is exposed by the pixel defining layer PDL. Accordingly, a cathode signal applied to the second power line PL2 may be supplied to the light emitting element LD through the cathode bridge layer CBR.

The light emitting element LD may be an organic light emitting diode. The light emitting element LD may include the first light emitting element LD1 which forms the first sub-pixel SPX1 and is disposed in the first sub-pixel area SPXA1, the second light emitting element which forms the second sub-pixel SPX2 and is disposed in the second sub-pixel area SPXA2, and the third light emitting element which forms the third sub-pixel SPX3 and is disposed in the third sub-pixel area SPXA3. The first light emitting element LD1 may be formed by the first anode electrode AE1, the first light emitting layer EL1, and a portion of the cathode electrode CE in the first sub-pixel area SPXA1. The second light emitting element LD2 may be formed by the second anode electrode AE2, the second light emitting layer EL2, and a portion of the cathode electrode CE in the second sub-pixel area SPXA2. The third light emitting element LD3 may be formed by the third anode electrode AE3, the third light emitting layer EL3, and a portion of the cathode electrode CE in the third sub-pixel area SPXA3.

The encapsulation layer TFE may be disposed on the light emitting element LD and the cathode electrode CE. The encapsulation layer TFE may remove a step difference formed by the light emitting elements LD, and passivate the light emitting elements LD.

The encapsulation layer TFE may include multiple layers. For example, the encapsulation layer TFE may include a first encapsulation layer, a second encapsulation layer, and a third encapsulation layer. In some embodiments, the first encapsulation layer may include an inorganic material, the second encapsulation layer may include an organic material, and the third encapsulation layer may include an inorganic material. However, the disclosure is not limited thereto.

The upper layer UL may be disposed on an upper portion of the display device DD in a display direction of the display device DD (e.g., third direction DR3), and include various layers. For example, the upper layer UL may include a cover window. The upper layer UL may include color filters. The upper layer UL may further include various functional film layers (e.g., a low reflective film and the like). However, the disclosure is not limited to a specific example.

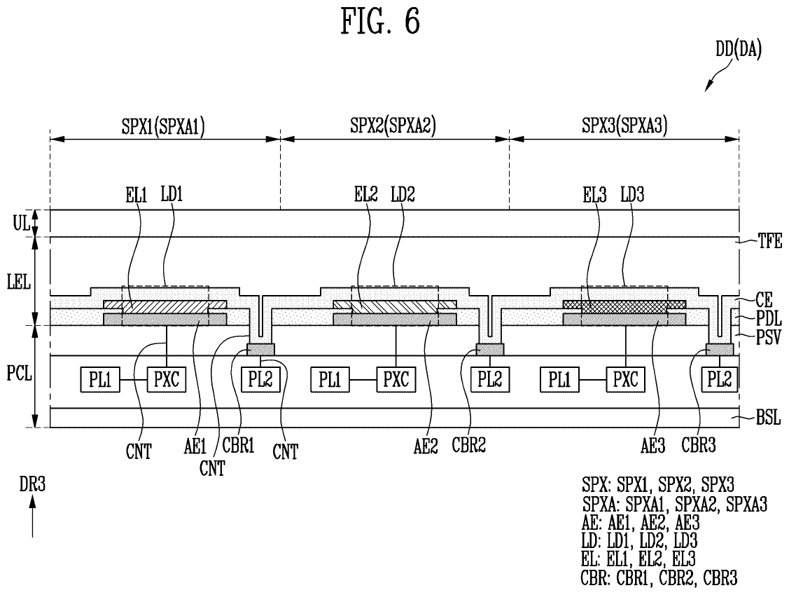

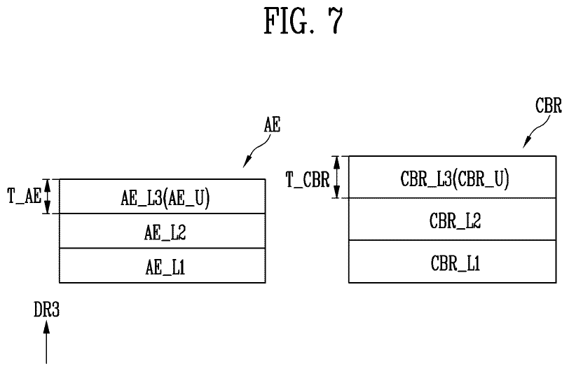

A display device DD in accordance with a second embodiment of the disclosure will be described with reference to FIGS. 6 and 7. In FIGS. 6 and 7, descriptions of portions overlapping the portions described above will be simplified or will not be repeated.

FIG. 6 is a schematic sectional view illustrating a display device in accordance with a second embodiment of the disclosure. FIG. 6 illustrates a sectional structure of the display device DD in the display area DA. FIG. 7 is a schematic sectional view illustrating an anode electrode and a cathode bridge layer in accordance with an embodiment of the disclosure.

In accordance with the second embodiment of the disclosure, the cathode bridge layer CBR may be included in the pixel-circuit layer PCL, and the residual sacrificial layer SCF_R may not be formed.

The top surface (or upper surface) of the cathode bridge layer CBR may be exposed by the protective layer PSV. A side surface of the cathode bridge layer CBR may overlap the protective layer PSV in the third direction DR3.

The cathode bridge layer CBR may be disposed between different anode electrodes AE adjacent to each other. The cathode bridge layer CBR may be disposed closer to the base layer BSL than the anode electrode AE in the third direction DR3. The cathode bridge layer CBR may be formed by some of the conductive layers for forming the pixel-circuit layer PCL. For example, the cathode bridge layer CBR may be disposed in a same layer as the source electrode and/or the drain electrode of the transistor included in the pixel circuit PXC, and include a same material as the source electrode and/or the drain electrode of the transistor included in the pixel circuit PXC. In some embodiments, the cathode bridge layer CBR in the pixel-circuit layer PCL may be electrically connected to the second power line PL2.

The cathode bridge layer CBR may be located adjacent to the protective layer PSV in a plan direction in which the base layer BSL is disposed (e.g., a direction in which a plan defined by the first direction DR1 and the second direction DR2 extends). The side surface of the cathode bridge layer CBR may face the protective layer PSV.

In some embodiments, the pixel defining layer PDL may cover the anode electrode AE, and be covered by the light emitting layer EL. A portion of the pixel defining layer PDL may be disposed between the anode electrode AE and the light emitting layer EL.

The cathode electrode CE may entirely cover a top surface (or upper surface) of the light emitting layer EL, and be electrically connected to the light emitting layer EL. The cathode electrode CE may also cover a side surface of the light emitting layer EL. A portion of the cathode electrode CE may be electrically connected to the cathode bridge layer CBR through the contact portion CNT penetrating the pixel defining layer PDL and the protective layer PSV. At least a portion of the cathode electrode CE may cover side surfaces of the protective layer PSV and the pixel defining layer PDL.

In this embodiment, the cathode bridge layer CBR may be disposed an area adjacent to the light emitting layer EL in the display area DA, and accordingly, a risk such as a voltage drop in the display device DD can be reduced.

As depicted in FIG. 7, the anode electrode AE may include multiple layers. The anode electrode AE may have a structure including an uppermost anode electrode portion AE_U and other layers which are disposed under the uppermost anode electrode portion AE_U. For example, the anode electrode AE may include a first anode electrode portion AE_L1 including a transparent conductive material, a second anode electrode portion AE_L2 disposed on the first anode electrode portion AE_L1 and including a reflective conductive material, and a third anode electrode portion AE_L3 disposed on the second anode electrode portion AE_L2 and including a transparent conductive material. For example, the first anode electrode portion AE_L1 may include ITO, the second anode electrode portion AE_L2 may include Ag, and the third anode electrode portion AE_L3 may include ITO. The third anode electrode portion AE_L3 may be the uppermost anode electrode portion AE_U. In some embodiments, the uppermost anode electrode portion AE_U (e.g., the third anode electrode portion AE_L3) may have a first thickness T_AE.

The cathode bridge layer CBR may include multiple layers. The cathode bridge layer CBR may have a structure including an uppermost cathode bridge portion CBR_U and other layers which are disposed under the uppermost cathode bridge portion CBR_U. For example, the cathode bridge layer CBR may include a first cathode bridge portion CBR_L1 including a first conductive material, a second cathode bridge portion CBR_L2 disposed on the first cathode bridge portion CBR_L1 and including a second conductive material, and a third cathode bridge portion CBR_L3 disposed on the second cathode bridge portion CBR_L2 and including a third conductive material. The first cathode bridge portion CBR_L1 may include Ti, the second cathode bridge portion CBR_L2 may include Al, and the third cathode bridge portion CBR_L3 may include Ti. The third cathode bridge portion CBR_L3 may be the uppermost cathode bridge portion CBR_U. In some embodiments, the uppermost cathode bridge portion CBR_U (e.g., the third cathode bridge portion CBR_L3) may have a second thickness T_CBR.

After the cathode bridge layer CBR is formed in the pixel-circuit layer PCL, processes of patterning the first to third light emitting layers EL1 to EL3 may be performed. During an etching process of the first to third light emitting layers EL1 to EL3, the cathode bridge layer CBR may be continuously exposed to a process environment. Accordingly, the second thickness T_CBR of the uppermost cathode bridge portion CBR_U as an uppermost layer of the cathode bridge layer CBR may be provided thick enough so that the structure of the cathode bridge layer CBR may be robust against the etching process. For example, the uppermost cathode bridge portion CBR_U including Ti which is robust against the etching process may have a thick thickness. In some embodiments, the second thickness T_CBR may be greater than the first thickness T_AE in the third direction DR3. For example, the second thickness T_CBR may be about 1000 Å or more, and the first thickness T_AE may be about 50 Å or more. For example, the second thickness T_CBR may be about 1000 Å to about 2000 Å, and the third thickness T_AE may be about 50 Å to about 100 Å. However, the disclosure is not limited to a specific numerical range.

A method of manufacturing the display device DD in accordance with the first embodiment of the disclosure will be described with reference to FIGS. 8 to 25. In FIGS. 8 to 25, descriptions of portions overlapping the portions described above will be simplified or will not be repeated.

FIGS. 8 to 25 are schematic sectional views illustrating process steps of a method of manufacturing the display device in accordance with the first embodiment of the disclosure. For convenience of descriptions, FIGS. 8 to 25 are illustrated based on the sectional structure described above with reference to FIG. 5.

FIGS. 8 to 25 illustrate process steps in which layers of a pixel-circuit layer PCL and a light emitting element LEL are formed in processes of manufacturing the display device DD.

Referring to FIG. 8, a first power line PL1, a second power line PL2, and a pixel circuit PXC may be patterned on a base layer BSL, and a protective layer PSV may be formed on the first power line PL1, the second power line PL2, and the pixel circuit PXC. Accordingly, a pixel-circuit layer PCL may be manufactured.

In some embodiments, a conductive layer or an insulating layer on the base layer BSL may be formed based on a process for manufacturing a semiconductor device. For example, the conductive layer or the insulating layer on the base layer BSL may be formed through a photolithography process, be etched through various processes (wet etching, dry etching, and the like), and be deposited through various processes (sputtering, chemical vapor deposition, and the like). However, the disclosure is not limited to a specific example.

In some embodiments, the second power line PL2 may be patterned through a same process as a source electrode and/or a drain electrode of the pixel circuit PXC. However, the disclosure is not limited thereto.

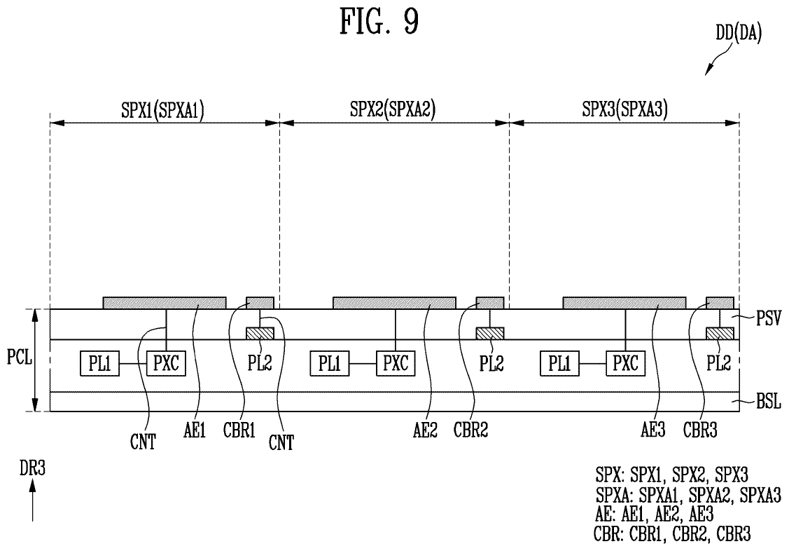

Referring to FIG. 9, an anode electrode AE and a cathode bridge layer CBR may be patterned on the pixel-circuit layer PCL.

In this step, the anode electrode AE and the cathode bridge layer CBR may be patterned through a same process, and have the substantially same structure.

In this step, holes penetrating the protective layer PSV may be formed. After forming the holes, as the anode electrode AE and the cathode bridge layer CBR are patterned, a contact portion CNT may be formed. Accordingly, the anode electrode AE may be electrically connected to the pixel circuit PXC through the contact portion CNT, and the cathode bridge layer CBR may be electrically connected to the second power line PL2.

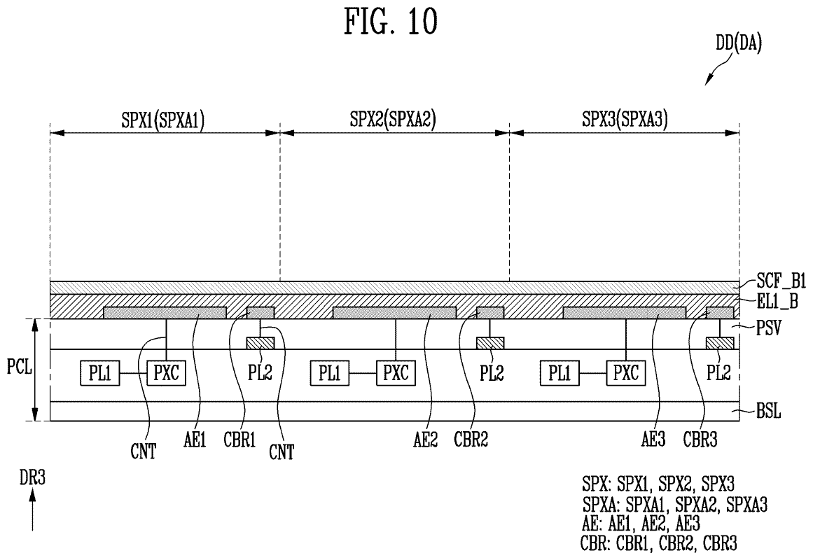

Referring to FIG. 10, a first base light emitting layer EL1_B and a first base sacrificial layer SCF_B1 may be formed on the anode electrode AE and the cathode bridge CBR.

The first base light emitting layer EL1_B may include a material for forming a first light emitting layer EL1 of a first sub-pixel SPX1. The first base sacrificial layer SCF_B1 may include a material for forming a residual sacrificial layer SCF_R.

In this step, the first base light emitting layer EL1_B and the first base sacrificial layer SCF_B1 may be disposed throughout first to third sub-pixel areas SPXA1 to SPXA3.

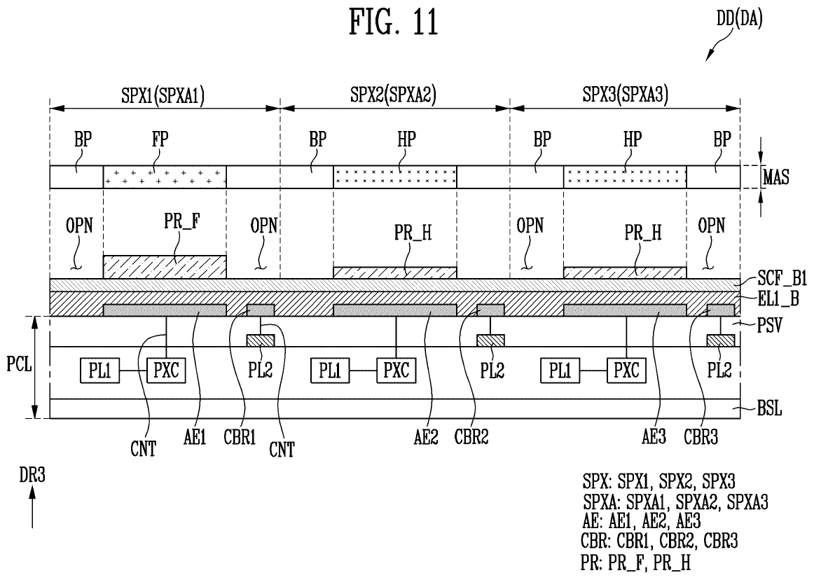

Referring to FIG. 11, a photoresist layer PR may be patterned on the first base sacrificial layer SCF_B1 using a mask MAS.

In some embodiments, the mask MAS may include a full-tone portion FP, a half-tone portion HP, and a blocking portion BP. The photoresist layer PR may include a first photoresist layer PR_F corresponding to a position of the full-tone portion FP and a second photoresist layer PR_H corresponding to a position of the half-tone portion HP in the third direction DR3. For example, the first photoresist layer PR_F may overlap the full-tone portion FP in a plan view, and the second photoresist layer PR_H may overlap the half-tone portion HP in a plan view. In some embodiments, the photoresist layer PR may form an etching mask structure, and include an opening OPN at a position corresponding to the blocking portion BP in the third direction DR3.

In some embodiments, as the photoresist layer PR is patterned using the mask MAS including the full-tone portion FP and the half-tone portion HP, the first photoresist layer PR_F may have a thickness which is thicker than a thickness of the second photoresist layer PR_H in the third direction DR3. For example, the photoresist layer PR may be manufactured using a negative photoresist. However, the disclosure is not limited thereto.

In some embodiments, a position of the first photoresist layer RP_F may overlap a position of a light emitting layer EL in the third direction DR3 to be manufactured. For example, the photoresist layer PR manufactured in this step may be an etch mask. In some embodiments, a position of the second photoresist layer PR_H may overlap a position of each of other light emitting layers EL in the third direction DR3 except the light emitting layer EL to be manufactured. For example, the position of the second photoresist layer PR_H may not overlap a position of each of the light emitting layer EL to be manufactured and the cathode bridge layer CBR. In some embodiments, a position of the opening OPN of the photoresist layer PR may overlap a position of a cathode bridge layer CBR in the third direction DR3 to be exposed.

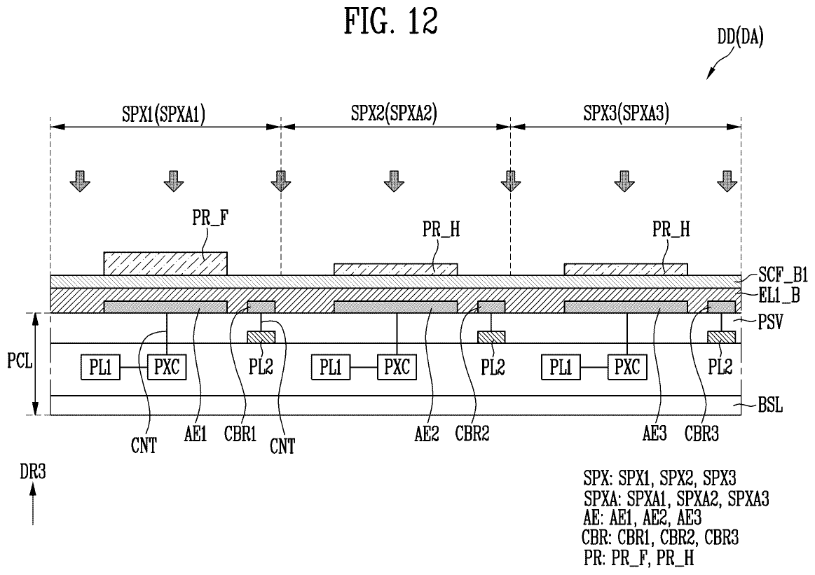

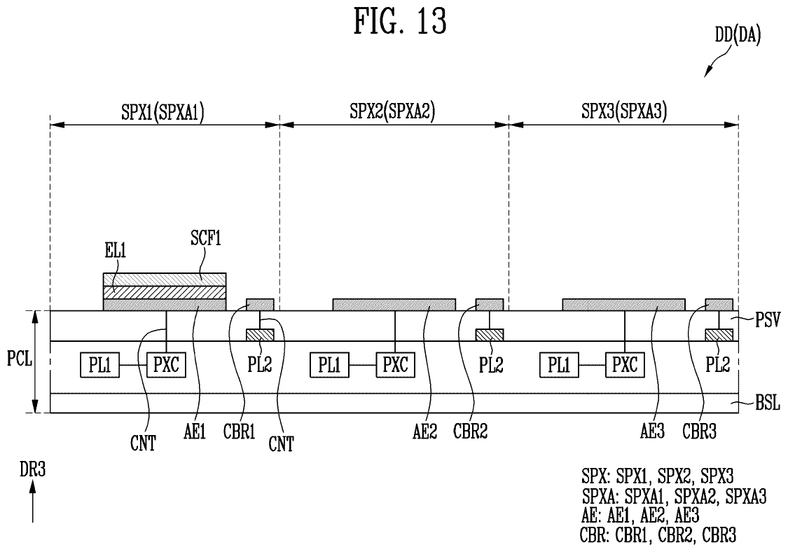

Referring to FIGS. 12 and 13, the first base light emitting layer EL1_B and the first base sacrificial layer SCF_B1 may be etched using the photoresist layer PR as an etch mask, and the first light emitting layer EL1 and a first sacrificial layer SCF1 may be provided.

In this step, as the mask MAS including the half-tone portion HP is used, a process of patterning the light emitting layer EL using a same etch mask (i.e., the photoresist layer PR) and a process of exposing the cathode bridge layer CBR may be performed. Accordingly, process steps are simplified so that the number of masks can be decreased. In addition, the convenience of manufacturing process can be improved, and process cost can also be reduced.

In this step, a portion of the first base light emitting layer EL1_B, which corresponds to the first photoresist layer PR_F having a relatively thick thickness, may not be removed, and accordingly, the first light emitting layer EL1 in the first sub-pixel area SPXA1 may be patterned.

In this step, the first base light emitting layer EL1_B and the first base sacrificial layer SCF_B1, which correspond to the opening OPN, may be removed, and the cathode bridge layer CBR may be exposed. In this step, the first base light emitting layer EL1_B and the first base sacrificial layer SCF_B1, which correspond to the second photoresist layer PR_H, may be removed. Accordingly, the first base light emitting layer EL1_B in the second and third sub-pixel areas SPXA2 and SPXA3 may be removed. In some embodiments, the first base sacrificial layer SCF_B1 may include aluminum (Al), and be removed based on a wet etching process. After the first light emitting layer EL1 and the first sacrificial layer SCF1 are manufactured, the photoresist layer PR may be removed based on an ashing process. Accordingly, the first light emitting layer EL1 and the first sacrificial layer SCF1 may be disposed on a first anode electrode AE1 in the first sub-pixel area SPXA1, second and third anode electrodes AE2 and AE3 may be exposed in the second sub-pixel areas SPXA2 and SPXA3, and first to third cathode bridge layers CBR1 to CBR3 may be exposed in the first to third sub-pixel areas SPXA1 to SPXA3.

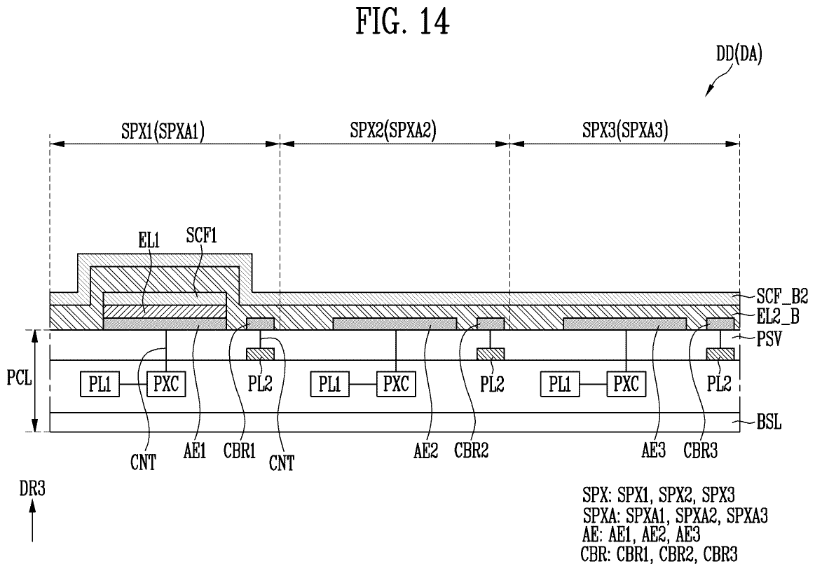

Referring to FIGS. 14 to 17, similarly to a process of forming the first light emitting layer EL1 and the first sacrificial layer SCF1, a second light emitting layer EL2 and a second sacrificial layer SCF2 may be manufactured. Accordingly, a process for patterning the second light emitting layer EL2 and a second sacrificial layer SCF2 will be clearly understood in conjunction with the above-described portions.

Referring to FIG. 14, a second base light emitting layer EL2_B and a second base sacrificial layer SCF_B2 may be formed over the first sacrificial layer SCF1, the second and third anode electrodes AE2 and AE3, and the cathode bridge layer CBR.

The second base light emitting layer EL2_B may include a material for forming the second light emitting layer EL2 of a second sub-pixel SPX2. The second base sacrificial layer SCF_B2 may include a material for forming the residual sacrificial layer SCF_R.

In this step, the second base light emitting layer EL2_B and the second base sacrificial layer SCF_B2 may be disposed throughout the first to third sub-pixel areas SPXA1 to SPXA3.

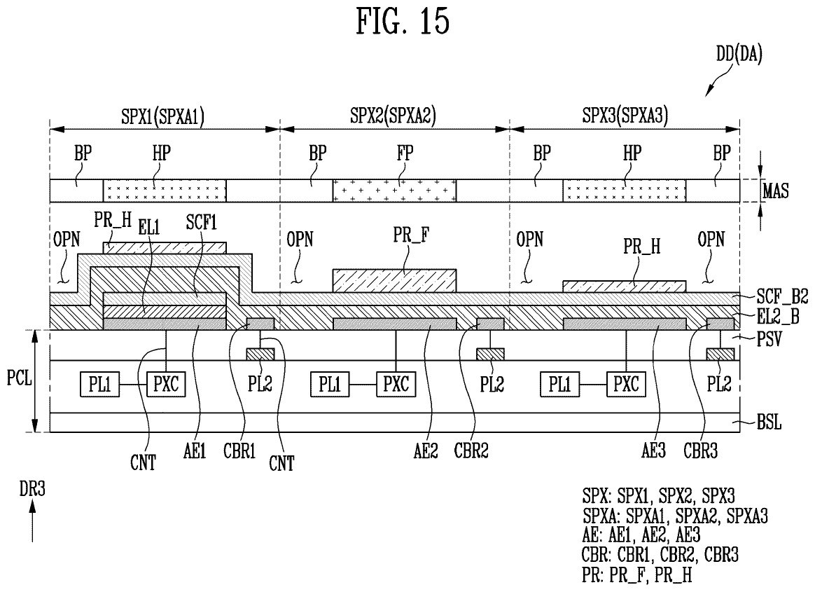

Referring to FIG. 15, a photoresist layer PR may be patterned on the second base sacrificial layer SCF_B2 using a mask MAS.

In some embodiments, the mask MAS may include a full-tone portion FP, a half-tone portion HP, and a blocking portion BP. A first photoresist layer PR_F corresponding to the full-tone portion FP may be disposed in the second sub-pixel area SPXA2 and a second photoresist layer PR_H corresponding to the half-tone portion HP may be disposed in the first and third sub-pixel areas SPXA1 and SPXA3. An opening OPN may overlap the cathode bridge layer CBR in a plan view.

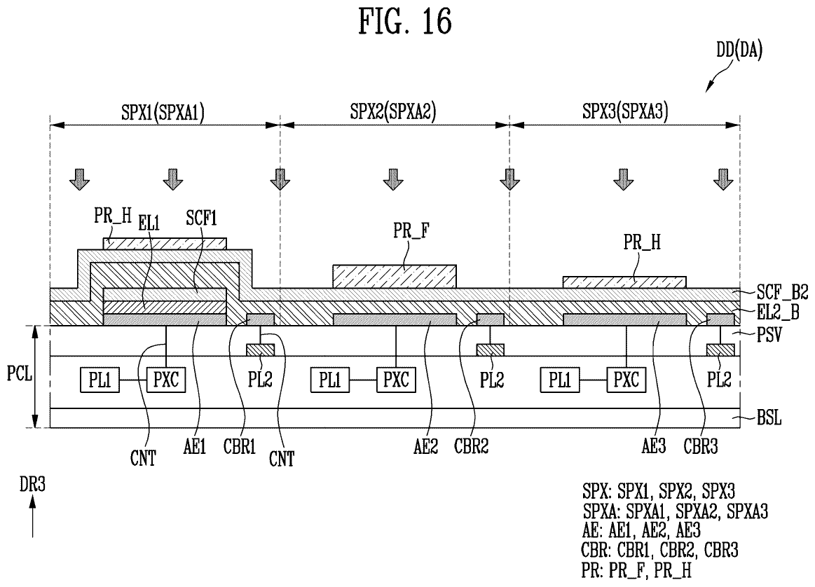

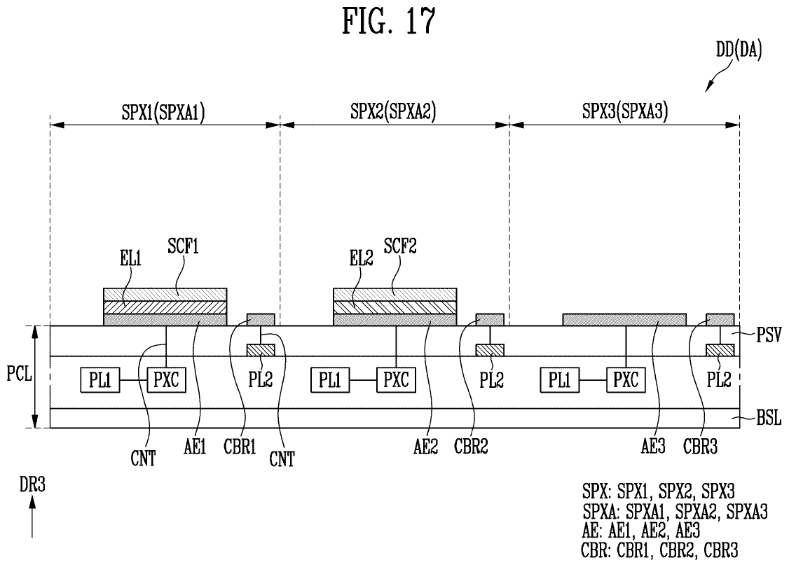

Referring to FIGS. 16 and 17, the second base light emitting layer EL2_B and the second base sacrificial layer SCF_B2 may be etched based on the photoresist layer PR manufactured using the mask MAS including the half-tone portion HP, and the second light emitting layer EL2 and the second sacrificial layer SCF2 may be provided.

In this step, the first to third cathode bridge layers CBR1 to CBR3 may be exposed, and the third anode electrode AE3 may be exposed.

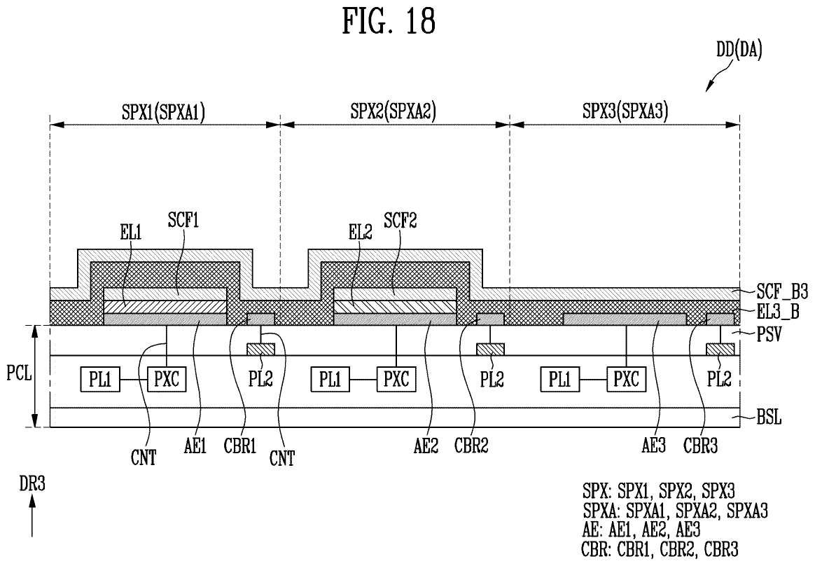

Referring to FIGS. 18 to 21, similarly to a process of forming the first and second light emitting layers EL1 and EL2 and the first and second sacrificial layers SCF1 and SCF2, a third light emitting layer EL3 and a third sacrificial layer SCF3 may be manufactured. Accordingly, a process for patterning the third light emitting layer EL3 and the third sacrificial layer SCF3 will be clearly understood in conjunction with the above-described portions.

Referring to FIG. 18, a third base light emitting layer EL3_B and a third base sacrificial layer SCF_B3 may be formed on the first and second sacrificial layers SCF1 and SCF2, the third anode electrode AE3, and the cathode bridge layer CBR.

The third base light emitting layer EL3_B may include a material for forming the third light emitting layer EL3 of a third sub-pixel SPX3. The third base sacrificial layer SCF_B3 may include a material for forming the residual sacrificial layer SCF_R.

In this step, the third base light emitting layer EL3_B and the third base sacrificial layer SCF_B3 may be disposed throughout the first to third sub-pixel areas SPXA1 to SPXA3.

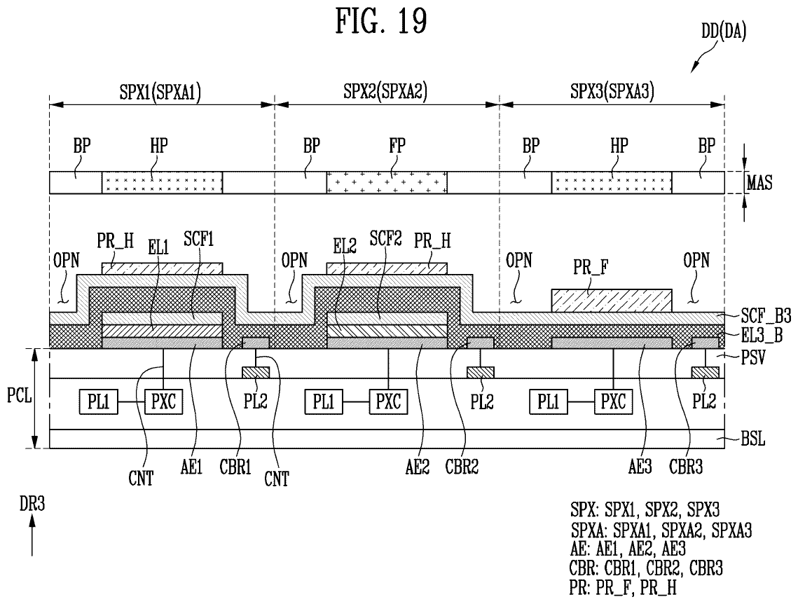

Referring to FIG. 19, a photoresist layer PR may be patterned on the third base sacrificial layer SCF_B3 using a mask MAS.

In some embodiments, the mask MAS may include a full-tone portion FP, a half-tone portion HP, and a blocking portion BP. A first photoresist layer PR_F corresponding to the full-tone portion FP may be disposed in the third sub-pixel area SPXA3, and a second photoresist layer PR_H corresponding to the half-tone portion HP in the third direction DR3 may be disposed in the first and second sub-pixel areas SPXA1 and SPXA2. An opening OPN may overlap the cathode bridge layer CBR in a plan view.

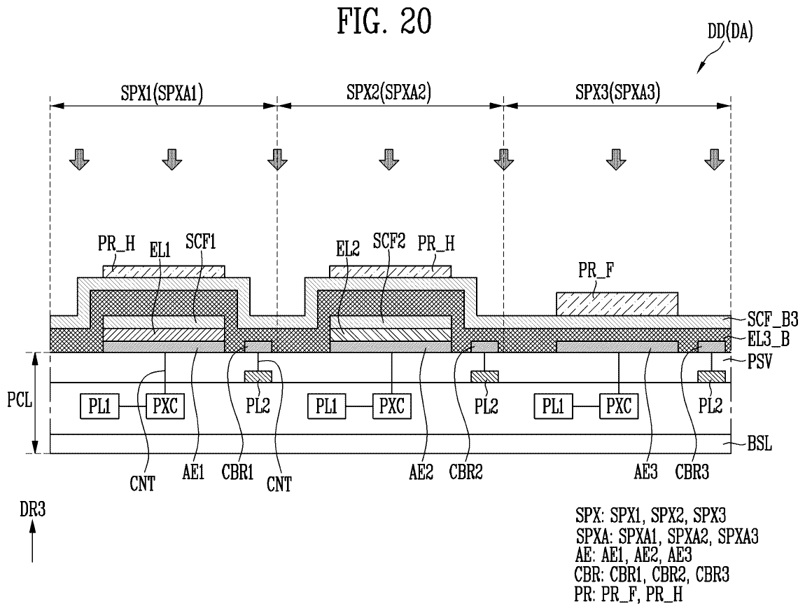

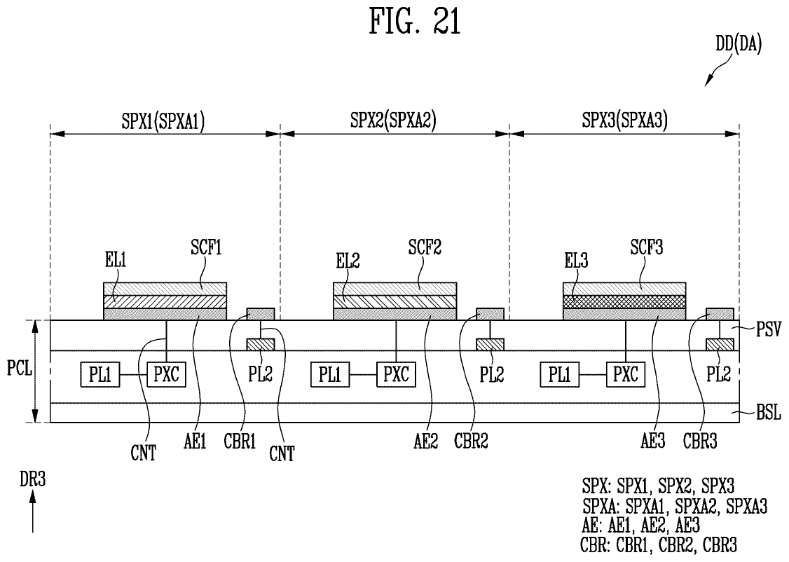

FIGS. 20 and 21, the third base light emitting layer EL3_B and the third base sacrificial layer SCF_B3 may be etched based on the photoresist layer PR manufactured using the mask MAS including the half-tone portion HP, and the third light emitting layer EL3 and the third sacrificial SCF3 may be provided.

In this step, the first to third cathode bridge layers CBR1 to CBR3 may be exposed, and the first to third light emitting layers EL1 to EL3 may be covered by the first to third sacrificial layers SCF1 to SCF3.

Meanwhile, in some embodiments, each of the first to third sacrificial layers SCF1 to SCF3 may cover each of the first to third light emitting layers EL1 to EL3 respectively. Accordingly, damage of the first to third light emitting layers EL1 to EL3 formed on the bottom of the first to third sacrificial layers SCF1 to SCF3 during a manufacturing process after each of the first to third sacrificial layers SCF1 to SCF3 is manufactured can be prevented.

In some embodiments, as described above, the cathode bridge layers CBR may be exposed several times during a process of patterning the first to third light emitting layers EL1 to EL3. Therefore, the cathode bridge layer CBR may be patterned through a same process as the anode electrode AE, but a top surface (or upper surface) of the cathode bridge layer CBR may have a roughness different from a roughness of the anode electrode AE.

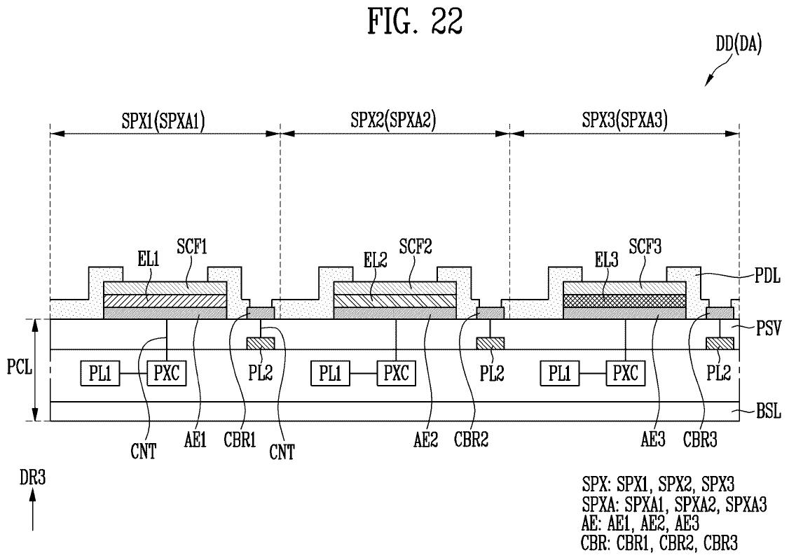

Referring to FIG. 22, a pixel defining layer PDL may be patterned, which partially covers the first to third sacrificial layers SCF1 to SCF3 and the first to third cathode bridge layers CBR1 to CBR3.

In this step, the pixel defining layer PDL may expose a portion of a top surface (or upper surface) of each of the first to third sacrificial layers SCF1 to SCF3 in each of the first to third sub-pixel areas SPXA1 to SPXA3. The pixel defining layer PDL may expose a portion of a top surface (or upper surface) of each of the first to third cathode bridge layers CBR1 to CBR3.

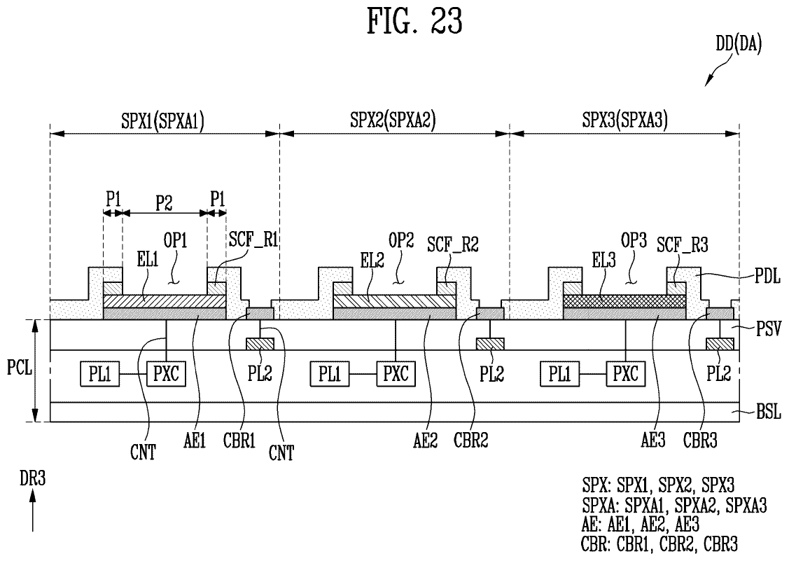

Referring to FIG. 23, as at least a portion of each of the first to third sacrificial layers SCF1 to SCF3 is removed, first to third openings OP1 to OP3 respectively exposing the first to third light emitting layers EL1 to EL3 may be formed.

In this step, a portion of each of the first to third sacrificial layers SCF1 to SCF3 on a second portion P2 of each of the anode electrodes AE is removed, and at least a portion of each of the first to third sacrificial layers SCF1 to SCF3 on a first portion P1 of each of the anode electrodes AE may remain. Accordingly, first to third residual sacrificial layers SCF_R1 to SCF_R3 may be provided.

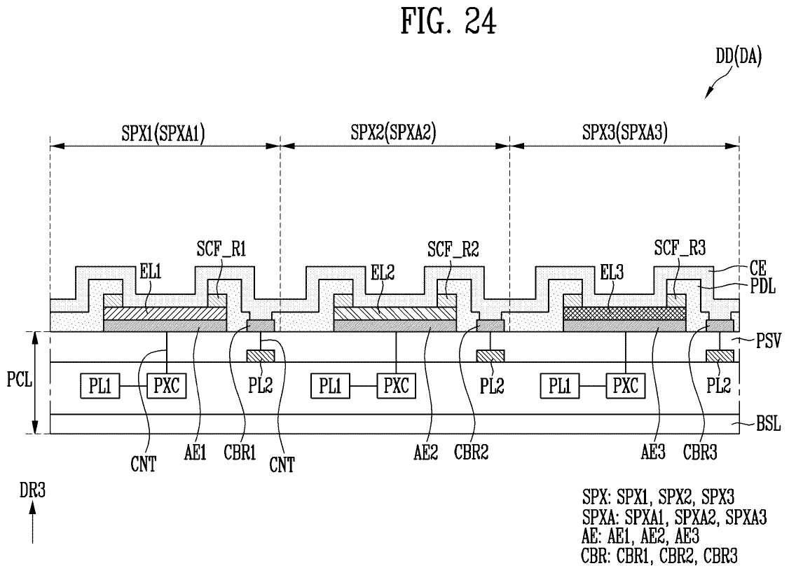

Referring to FIG. 24, a cathode electrode CE may be formed throughout the first to third sub-pixel areas SPXA1 to SPXA3.

In this step, at least a portion of the cathode electrode CE may be electrically connected to the first to third light emitting layers EL1 to EL3. At least another portion of the cathode electrode CE may be electrically connected to the exposed top surface (or upper surface) of each of the first to third cathode bridge layers CBR1 to CBR3.

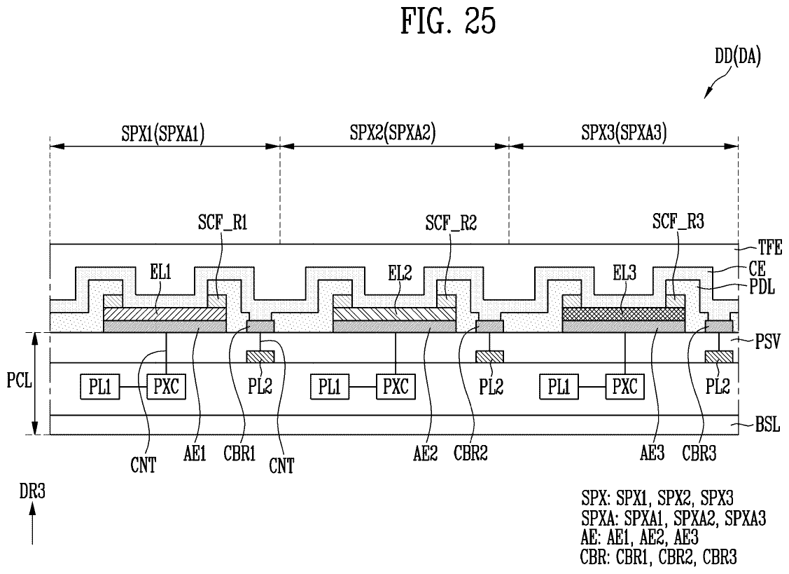

Referring to FIG. 25, an encapsulation layer TFE covering the cathode electrode CE may be formed. In this step, a first encapsulation layer including an inorganic material, a second encapsulation layer including an organic material, and a third encapsulation layer including an inorganic material may be sequentially formed so as to form the encapsulation TFE. After that, in some embodiments, an upper layer UL may be formed on the encapsulation layer TFE, and the display device DD in accordance with the first embodiment of the disclosure may be provided.

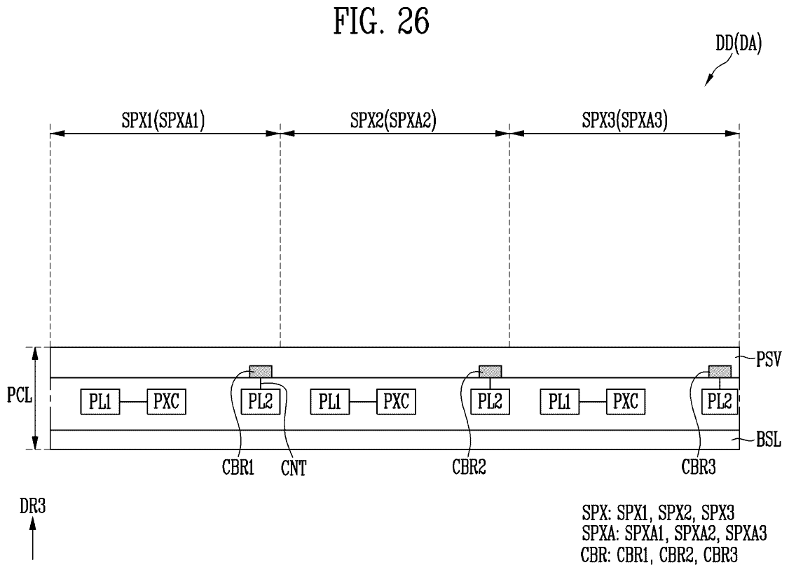

A method of manufacturing the display device DD in accordance with the second embodiment of the disclosure will be described with reference to FIGS. 26 to 36. In FIGS. 26 to 36, descriptions of portions overlapping with the portions described above will be simplified or will not be repeated.

FIGS. 26 to 36 are schematic sectional views illustrating process steps of a method of manufacturing the display device in accordance with the second embodiment of the disclosure. For convenience of description, FIGS. 26 to 36 are illustrated based on the sectional structure described above with reference to FIG. 6.

Referring to FIG. 26, a first power line PL1, a second power line PL2, a pixel circuit PXC, and a cathode bridge layer CBR may be patterned on a base layer BSL, and a protective layer PSV may be formed on the first power line PL1, the second power line PL2, the pixel circuit PXC, and the cathode bridge layer CBR. Accordingly, a pixel-circuit layer PCL may be manufactured.

In this step, in some embodiments, each of first to third cathode bridge layers CBR1 to CBR3 may be electrically connected to the second power line PL2 through a contact portion CNT penetrating at least one insulating layer of the pixel-circuit layer PCL. In some embodiments, the first to third cathode bridge layers CBR1 to CBR3 may be patterned through a same process as a source electrode and/or a drain electrode of a transistor included in the pixel circuit PXC.

In this step, the first to third cathode bridge layers CBR1 to CBR3 may be entirely covered by the protective layer PSV.

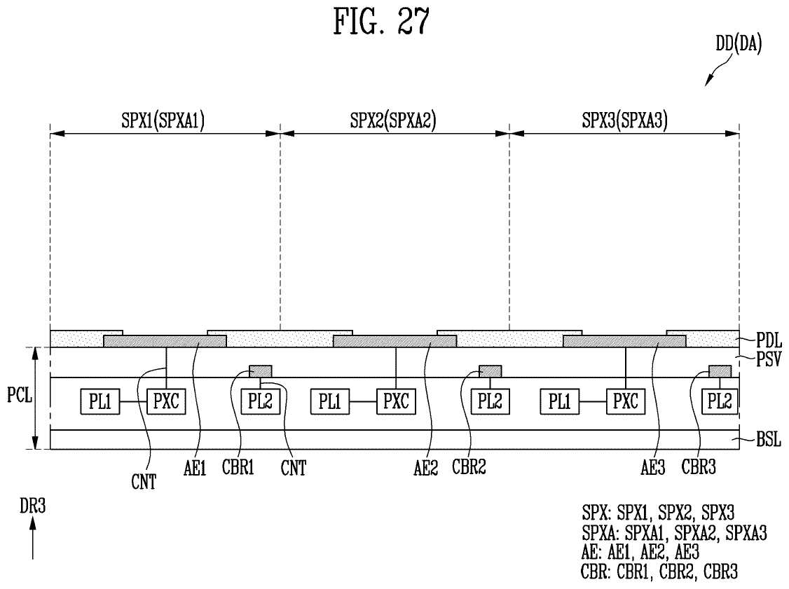

Referring to FIG. 27, first to third anode electrodes AE1 to AE3 may be patterned on the protective layer PSV, and a pixel defining layer PDL may be patterned, which partially covers each of the first to third anode electrodes AE1 to AE3.

In this step, each of the first to third anode electrodes AE1 to AE3 may be electrically connected to the pixel circuit PXC through a contact portion CNT penetrating through the protective layer PSV.

In this step, the pixel defining layer PDL may be formed to overlap the first to third cathode bridge layers CBR1 to CBR3 in a plan view.

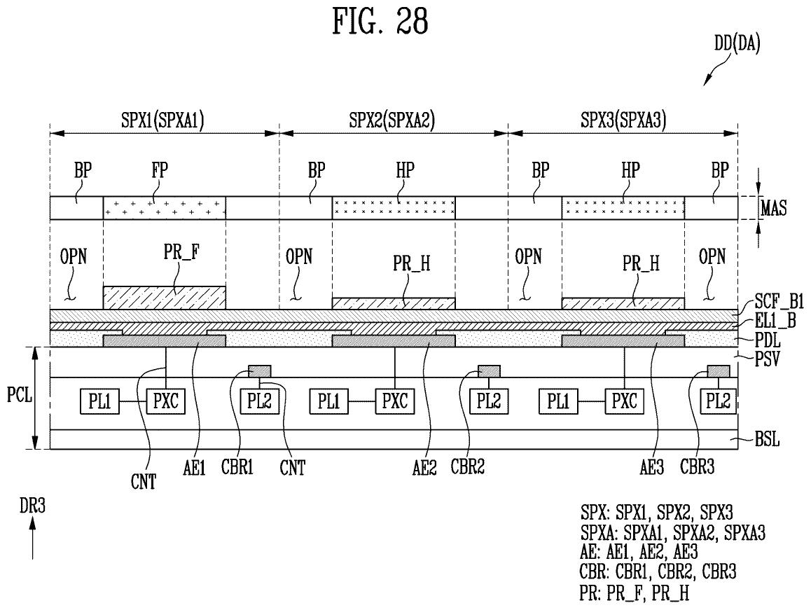

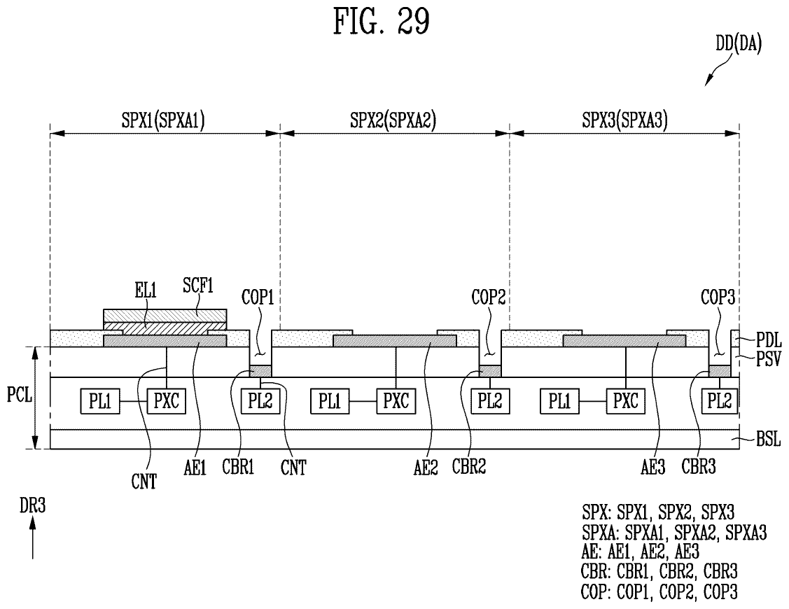

Referring to FIGS. 28 and 29, a first base light emitting layer EL1_B and a first base sacrificial layer SCF_B1 may be formed on the first to third anode electrodes AE1 to AE3 and the pixel defining layer PDL, and an etching process may be performed based on a photoresist layer PR manufactured using a mask MAS. Accordingly, a first light emitting layer EL1 and a first sacrificial layer SCF1 may be provided.

In this step, the mask MAS may include a full-tone portion FP, a half-tone portion HP, and a blocking portion BP. A first photoresist layer PR_F corresponding to the full-tone portion FP in the third direction DR3 may be disposed in a first sub-pixel area SPXA1, and a second photoresist layer PR_H corresponding to the half-tone portion HP in the third direction DR3 may be disposed in second and third sub-pixel areas SPXA2 and SPXA3 respectively. An opening OPN corresponding to the blocking portion BP may overlap a cathode bridge layer CBR in a plan view.

In this step, the second anode electrode AE2 and the third anode electrode AE3 may be exposed. In this step, at least a portion of each of the pixel defining layer PDL and the protective layer PSV may be etched using the mask MAS, and a top surface (or upper surface) of the cathode bridge layer CBR may be exposed. For example, as at least a portion of each of the pixel defining layer PDL and the protective layer PSV is removed using the mask MAS, a lower exposure hole COP may be formed. The lower exposure hole COP may include a first lower exposure hole COP1 exposing the first cathode bridge layer CBR1, a second lower exposure hole COP2 exposing the second cathode bridge layer CBR2, and a third lower exposure hole COP3 exposing the third cathode bridge layer CBR3.

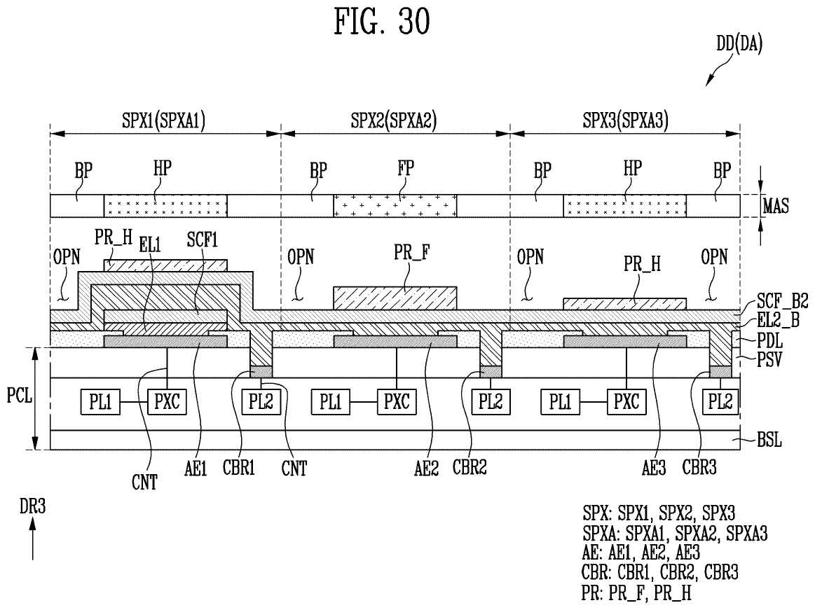

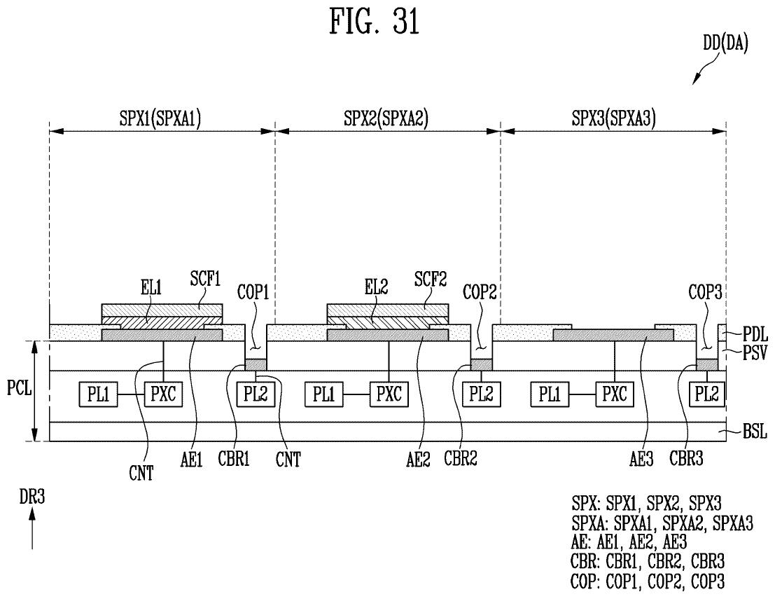

Referring to FIGS. 30 and 31, a second base light emitting layer EL2_B and a second base sacrificial layer SCF_B2 may be formed on the first sacrificial layer SCF1, the second and third anode electrodes AE2 and AE3, and the pixel defining layer PDL, and an etching process may be performed based on a photoresist layer PR manufactured using a mask MAS. Accordingly, a second light emitting layer EL2 and a second sacrificial layer SCF2 may be provided.

In this step, the mask MAS may include a full-tone portion FP, a half-tone portion HP, and a blocking portion BP. A first photoresist layer PR_F corresponding to the full-tone portion FP in the third direction DR3 may be disposed in the second sub-pixel area SPXA2, and a second photoresist layer PR_H corresponding to the half-tone portion HP in the third direction DR3 may be disposed in the first and third sub-pixel areas SPXA1 and SPXA3 respectively. An opening OPN corresponding to the blocking portion BP may overlap the cathode bridge layer CBR in a plan view.

In this step, the third anode electrode AE3 may be exposed. In this step, at least a portion of each of the pixel defining layer PDL and the protective layer PSV may be etched using the mask MAS, and the top surface (or upper surface) of the cathode bridge layer CBR may be exposed. For example, as at least a portion of each of the pixel defining layer PDL and the protective layer PSV is again removed using the mask MAS, the lower exposure hole COP may be again formed.

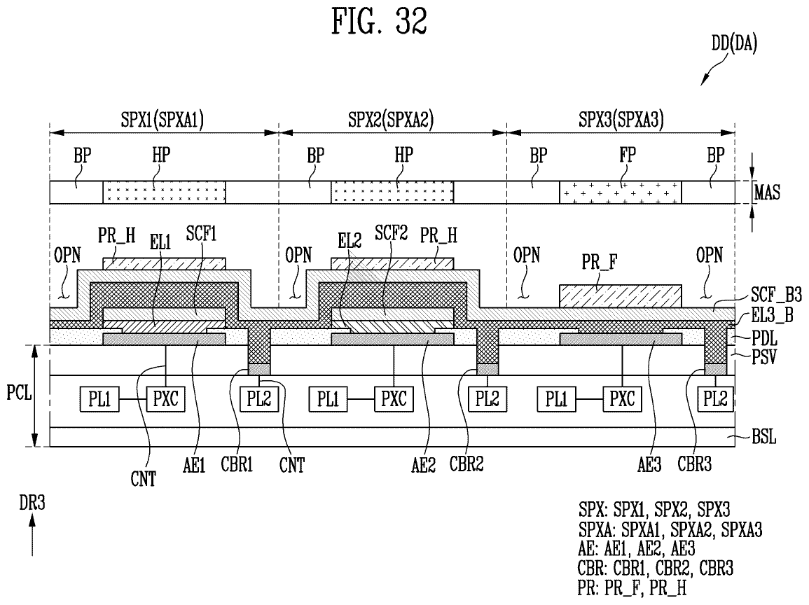

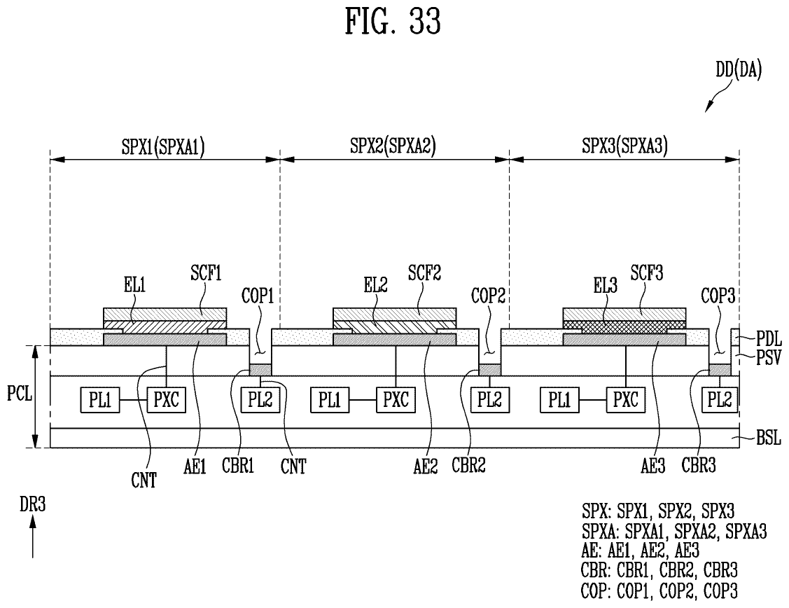

Referring to FIGS. 32 and 33, a third base light emitting layer EL3_B and a third base sacrificial layer SCF_B3 may be formed on the first and second sacrificial layers SCF1 and SCF2, the third anode electrode AE3, and the pixel defining layer PDL, and an etching process may be performed based on a photoresist layer PR manufactured using a mask MAS. Accordingly, a third light emitting layer EL3 and a third sacrificial layer SCF3 may be provided.

In this step, the mask MAS may include a full-tone portion FP, a half-tone portion HP, and a blocking portion BP. A first photoresist layer PR_F corresponding to the full-tone portion FP in the third direction DR3 may be disposed in the third sub-pixel area SPXA3, and a second photoresist layer PR_H corresponding to the half-tone portion HP in the third direction DR3 may be disposed in the first and second sub-pixel areas SPXA1 and SPXA2 respectively. An opening OPN corresponding to blocking portion BP may overlap the cathode bridge layer CBR in a plan view.

In this step, the first to third anode electrodes AE1 to AE3 may be covered by the first to third sacrificial layers SCF1 to SCF3, respectively. In this step, at least a portion of each of the pixel defining layer PDL and the protective layer PSV may be etched using the mask MAS, and the top surface (or upper surface) of the cathode bridge layer CBR may be exposed. For example, as at least a portion of each of the pixel defining layer PDL and the protective layer PSV is again removed using the mask MAS, the lower exposure hole COP may be again formed.

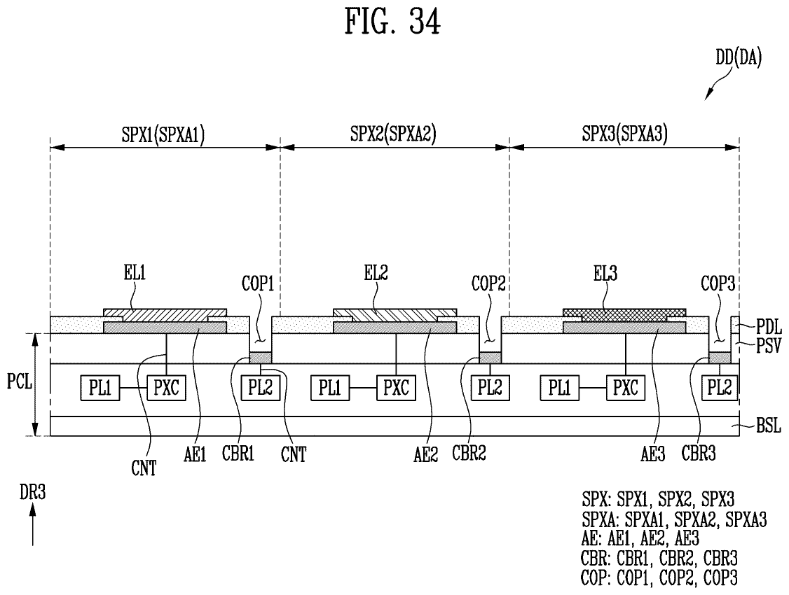

Referring to FIG. 34, the first to third sacrificial layers SCF1 to SCF3 may be removed. In this step, a wet etching process for removing the first to third sacrificial layers SCF1 to SCF3 may be performed, and top surfaces (or upper surfaces) of the first to third light emitting layers EL1 to EL3 may be exposed (e.g., entirely exposed).

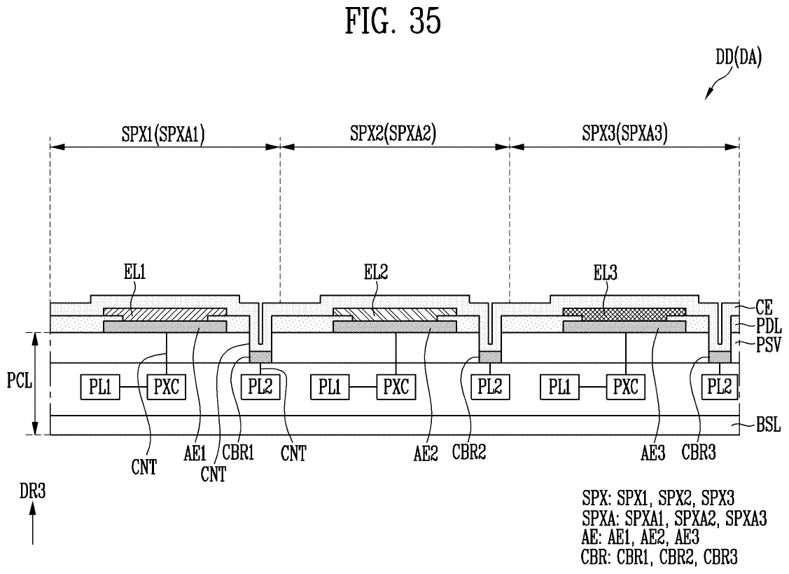

Referring to FIG. 35, a cathode electrode CE may be formed throughout the first to third sub-pixel areas SPXA1 to SPXA3.

In this step, at least a portion of the cathode electrode CE may be electrically connected to the first to third light emitting layers EL1 to EL3. At least another portion may be electrically connected to top surfaces (or upper surfaces) of the first to third cathode bridge layers CBR1 to CBR3 exposed adjacent to the protective layer PSV.

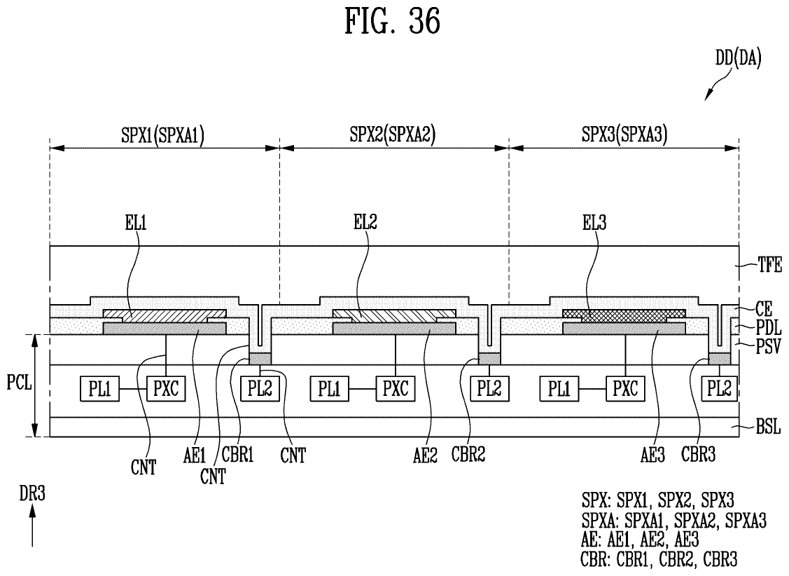

Referring to FIG. 36, an encapsulation layer TFE covering the cathode electrode CE may be formed. In this step, a first encapsulation layer including an inorganic material, a second encapsulation layer including an organic material, and a third encapsulation layer including an inorganic material may be sequentially formed to form the encapsulation TFE. In some embodiments, an upper layer UL may be formed on the encapsulation layer TFE, and the display device DD in accordance with the second embodiment of the disclosure may be provided.

Hereinafter, an electronic device 1000 including the display device DD in accordance with an embodiment will be described.

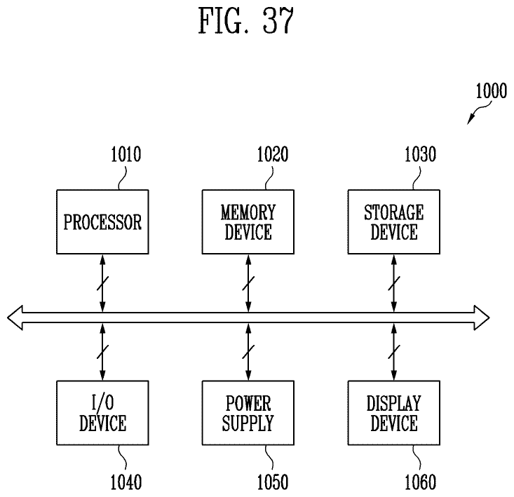

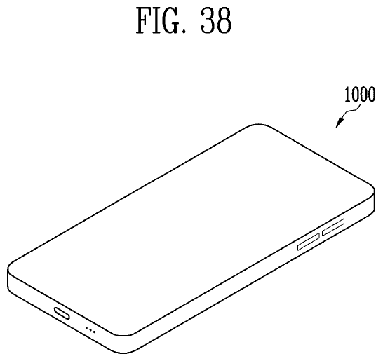

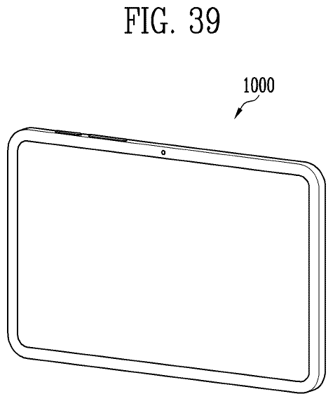

FIG. 37 is a schematic block diagram illustrating an electronic device 1000 including a display device in accordance with an embodiment. FIG. 38 is a schematic diagram illustrating an example where the electronic device 1000 of FIG. 37 is implemented as a smartphone. FIG. 39 is a schematic diagram illustrating an example where the electronic device 1000 of FIG. 37 is implemented as a tablet computer.

Referring to FIGS. 37 to 39, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 38, the electronic device 1000 may be implemented as a smartphone. In an embodiment, as illustrated in FIG. 29, the electronic device 1000 may be implemented as a tablet computer. However, the aforementioned examples are illustrative, and the electronic device 1000 is not necessarily limited to the aforementioned examples. For example, the electronic device 1000 may be implemented as a cellular phone, a video phone, a smartpad, a smartwatch, a navigation device for vehicles, a computer monitor, a laptop computer, a head-mounted display device, or the like.

The processor 1010 may perform specific calculations or tasks. In an embodiment, the processor 1010 may be a micro-processor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. For example, the memory device 1020 may include non-volatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or volatile memory devices such as a dynamic random access memory (DRAM) device, a static random access memory (SRAM) device, a mobile DRAM device, and so on.

The storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be included in the I/O device 1040.

The power supply 1050 may supply power needed to perform the operation of the electronic device 1000. For example, the power supply 1050 may be a power management integrated circuit (PMIC). In an embodiment, the power supply 1050 may supply power to the display device 1060.

The display device 1060 may display an image corresponding to visual information of the electronic device 1000. The display device 1060 may be connected to other components through the buses or other communication links.

In accordance with the disclosure, there can be provided a display device, a method of manufacturing a display device, and an electronic device comprising a display device, in which a voltage drop risk of a cathode electrode is reduced.

In accordance with the disclosure, there can be provided a display device having improved display quality and a method of manufacturing a display device having improved display quality.

In accordance with the disclosure, there can be provided a display device, a method of manufacturing a display device, and an electronic device comprising a display device, in which process steps are simplified, to improve convenience of manufacturing processes and reduce process cost.

However, the effects of the disclosure are not restricted to the one set forth herein. The above and other effects of the disclosure will become more apparent to one of daily skill in the art to which the disclosure pertains by referencing the claims. The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a base layer;
an anode electrode disposed on the base layer, the anode electrode including a first portion and a second portion;
a light emitting layer disposed on the anode electrode;
a cathode bridge layer disposed on the base layer, the cathode bridge layer being disposed in a same layer as the anode electrode and spaced part from the anode electrode;
a residual sacrificial layer disposed on the first portion of the light emitting layer; and
a cathode electrode disposed on the light emitting layer, the cathode electrode including a portion disposed on the second portion of the light emitting layer, the cathode electrode including another portion disposed on the cathode bridge layer.

2. The display device of claim 1, further comprising:
a first power line and a second power line, disposed on the base layer, the first power line and the second power line, respectively forming a first voltage potential and a second voltage potential, wherein
the first power line and the second power line are disposed closer to the base layer than the cathode bridge layer in a thickness direction,
the anode electrode includes anode electrodes adjacent to each other, and
the cathode bridge layer is disposed between the adjacent anode electrodes, and is electrically connected to the second power line.

3. The display device of claim 1, wherein the anode electrode and the cathode bridge layer include a structure in which a transparent conductive material, a reflective conductive material, and a transparent conductive material are sequentially disposed.

4. The display device of claim 3, wherein
the anode electrode and the cathode bridge layer include a structure in which ITO/Ag/ITO are sequentially stacked in a thickness direction,
the cathode electrode includes a silver-magnesium (AgMg) alloy, and
the residual sacrificial layer includes aluminum (Al).

5. The display device of claim 1, further comprising:
a pixel defining layer exposing the second portion of the anode electrode and the cathode bridge layer, wherein
an upper surface and an outer surface of the residual sacrificial layer are covered by the pixel defining layer, and
an inner surface of the residual sacrificial layer is exposed by the pixel defining layer, and is in direct contact with the cathode electrode.

6. The display device of claim 1, further comprising:
a display area including sub-pixel areas including a first sub-pixel area, a second sub-pixel area, and a third sub-pixel area, wherein
the anode electrode, the light emitting layer, and the cathode electrode form a light emitting element defined in the display area,
the cathode bridge layer is disposed in the display area, and
the light emitting element includes a first light emitting element which is formed in the first sub-pixel area and provides light of a first color, a second light emitting element which is formed in the second sub-pixel area and provides light of a second color, and a third light emitting element which is formed in the third sub-pixel area and provides light of a third color.

7. A display device comprising:
a base layer;
a pixel-circuit layer disposed on the base layer, the pixel-circuit layer including a pixel circuit, a protective layer covering the pixel circuit, and a cathode bridge layer adjacent to the protective layer in a plan direction in which the base layer is disposed;
a light emitting element disposed on the pixel-circuit layer; and
a pixel defining layer disposed on the pixel-circuit layer, wherein
the light emitting element includes an anode electrode disposed on the protective layer, a light emitting layer including a portion disposed on the anode electrode, and a cathode electrode including a portion disposed on the light emitting layer,
the pixel defining layer covers a portion of the anode electrode, and
another portion of the cathode electrode is electrically connected to the cathode bridge layer through a contact portion penetrating the pixel defining layer and the protective layer.

8. The display device of claim 7, wherein
the cathode electrode covers an upper surface of the light emitting layer and a side surface of the light emitting layer, and
a portion of the pixel defining layer is disposed between the light emitting layer and the anode electrode.

9. The display device of claim 7, wherein
the anode electrode includes an uppermost anode electrode portion having a first thickness in a thickness direction,
the cathode bridge layer includes an uppermost cathode bridge portion having a second thickness in the thickness direction, and
the second thickness is greater than the first thickness.

10. The display device of claim 9, wherein
the uppermost anode electrode portion includes ITO, and the first thickness is about 50 Å to about 100 Å, and
the uppermost cathode bridge portion includes Ti, and the second thickness is about 1000 Å to about 2000 Å.

11. The display device of claim 7, wherein
the pixel circuit includes a transistor including a source electrode and a drain electrode, and
the cathode bridge layer, the source electrode, and the drain electrode are formed in a same layer.

12. A method of manufacturing a display device, the method comprising:
forming a pixel-circuit layer including a pixel circuit disposed on a base layer;
patterning an anode electrode and a cathode bridge layer disposed on the pixel-circuit layer;
forming a base light emitting layer and a base sacrificial layer, which cover the anode electrode and the cathode bridge layer;
patterning, on the base sacrificial layer, a photoresist layer including an opening, a first photoresist layer, and a second photoresist layer, using a mask including a half-tone portion, a full-tone portion, and a blocking portion, wherein the first photoresist layer corresponds to a position of the full-tone portion in a thickness direction and the second photoresist layer corresponds to a position of the half-tone portion in the thickness direction; and
etching the base light emitting layer and the base sacrificial layer, based on the photoresist layer,
wherein the etching of the base light emitting layer and the base sacrificial layer includes:
providing a light emitting layer by removing a portion of the base light emitting layer; and
exposing the cathode bridge layer.

13. The method of claim 12, wherein, in the etching of the base light emitting layer and the base sacrificial layer, the first photoresist layer overlaps a position of the light emitting layer to be manufactured, the second photoresist layer does not overlap the light emitting layer and the cathode bridge layer, and the opening overlaps the cathode bridge layer.

14. The method of claim 12, wherein the exposing of the cathode bridge layer and the providing of the light emitting layer are performed based on the photoresist layer as a same etch mask.

15. The method of claim 12, wherein the patterning of the anode electrode and the patterning of the cathode bridge layer are performed through a same process.

16. The method of claim 12, wherein
the etching of the base light emitting layer and the base sacrificial layer includes forming a sacrificial layer on the light emitting layer by removing at least a portion of the base sacrificial layer, using a wet etching process,
the method further comprises:
patterning a pixel defining layer exposing at least a portion of the sacrificial layer and at least a portion of the cathode bridge layer;
exposing the light emitting layer by removing at least a portion of the sacrificial layer; and
forming a cathode electrode electrically connected to the light emitting layer and the cathode bridge layer, and
the exposing of the light emitting layer includes forming a residual sacrificial layer disposed on a portion of the light emitting layer.

17. A method of manufacturing a display device, the method comprising:
forming, on a base layer, a pixel-circuit layer including a pixel circuit, a cathode bridge layer, and a protective layer covering the pixel circuit and the cathode bridge layer;
patterning, on the pixel-circuit layer, an anode electrode and a pixel defining layer covering the anode electrode;
forming a base light emitting layer and a base sacrificial layer, which cover the anode electrode and the pixel defining layer;
patterning, on the base sacrificial layer, a photoresist layer including a first photoresist layer and a second photoresist layer, using a mask including a half-tone portion, a full-tone portion, and a blocking portion, wherein the first photoresist layer corresponds to a position of the full-tone portion in a thickness direction and the second photoresist layer corresponds to a position of the half-tone portion in the thickness direction; and
etching the base light emitting layer, the base sacrificial layer, the pixel defining layer, and the protective layer, based on the photoresist layer,
wherein the etching of the base light emitting layer includes:
providing a light emitting layer by removing a portion of the base light emitting layer; and
exposing the cathode bridge layer.

18. The method of claim 17, wherein
the pixel circuit includes a transistor including a source electrode and a drain electrode, and
the cathode bridge layer is formed through a same process as the source electrode and the drain electrode.

19. The method of claim 17, wherein
the etching of the base light emitting layer includes forming a sacrificial layer on the light emitting layer by removing at least a portion of the base sacrificial layer, using a wet etching process, and
the exposing of the cathode bridge layer includes forming a lower exposure hole penetrating the protective layer and the pixel defining layer.

20. The method of claim 19, further comprising:
entirely exposing un upper surface of the light emitting layer by removing the sacrificial layer; and
forming a cathode electrode, wherein
a portion of the cathode electrode is electrically connected to the light emitting layer, and
another portion of the cathode electrode is electrically connected to the cathode bridge layer through the lower exposure hole.

21. An electronic device, comprising:
a processor that provides input image data;
a display device that displays an image based on the input image data, the display device including sub-pixel areas; and
a power supply that supplies power to the display device,
wherein the display device includes:
a base layer;
an anode electrode disposed on the base layer, the anode electrode including a first portion and a second portion;
a light emitting layer disposed on the anode electrode;
a cathode bridge layer disposed on the base layer, the cathode bridge layer being disposed in a same layer as the anode electrode and spaced apart from the anode electrode;
a residual sacrificial layer disposed on the first portion of the light emitting layer; and
a cathode electrode disposed on the light emitting layer, the cathode electrode including a portion disposed on the second portion of the light emitting layer, the cathode electrode including another portion disposed on the cathode bridge layer.
